(19) United States
(12) Patent Application Publication
(10) Pub. No.: US 2024/0049562 A1
(43) Pub. Date: Feb. 8, 2024

(54) DISPLAY DEVICE AND METHOD FOR MANUFACTURING DISPLAY DEVICE

(71) Applicant: SEMICONDUCTOR ENERGY LABORATORY CO., LTD., Atsugi-shi, Kanagawa-ken (JP)

(72) Inventors: Yuichi YANAGISAWA, Atsugi, Kanagawa (JP); Shinya SASAGAWA, Chigasaki, Kanagawa (JP); Takashi HAMADA, Atsugi, Kanagawa (JP)

(21) Appl. No.: 18/257,617

(22) PCT Filed: Dec. 6, 2021
(86) PCT No.: PCT/IB2021/061349

§ 371 Date: Jun. 15, 2023

(30) Foreign Application Priority Data
Dec. 18, 2020 (JP) 2020-209858

(51) Int. Cl. H10K 59/80; H10K 59/12

(52) U.S. Cl. CPC H10K 59/80518; H10K 59/1201; H10K 59/80517; H10K 59/35

(57) ABSTRACT

A display device with high resolution is provided. The display device includes a first conductor, a first insulator over the first conductor, a second conductor provided inside an opening of the first insulator, a first light-emitting layer in contact with a top surface of the second conductor and a top surface of the first insulator, and a third conductor in contact with a top surface of the first light-emitting layer.

### TECHNICAL FIELD

One embodiment of the present invention relates to a display device and a display module. One embodiment of the present invention relates to a method for manufacturing a display device.

Note that one embodiment of the present invention is not limited to the above technical field. Examples of a technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof. Note that in this specification and the like, a semiconductor device generally means a device that can function by utilizing semiconductor characteristics.

### BACKGROUND ART

In recent years, higher-resolution display panels have been required. As a device that requires a high-resolution display panel, for example, devices for virtual reality (VR), augmented reality (AR), substitutional reality (SR), or mixed reality (MR) are given and have been actively developed in recent years.

Examples of a display device that can be used for a display panel include, typically, a liquid crystal display device, a light-emitting device including a light-emitting element such as an organic EL (Electro Luminescence) element or a light-emitting diode (LED), and electronic paper performing display by an electrophoretic method or the like.

For example, the basic structure of an organic EL element is a structure in which a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device and the like; thus, a thin, lightweight, high-contrast, and low-power display device can be achieved. Patent Document 1, for example, discloses an example of a display device using an organic EL element. [Reference][Patent Document]

[Patent Document 1] Japanese Published Patent Application No. 2002-324673

### SUMMARY OF THE INVENTION

### Problems to be Solved by the Invention

For example, in the above-described device for VR, AR, SR, or MR that is wearable, a lens for focus adjustment needs to be provided between eyes and the display panel. Since part of the screen is enlarged by the lens, low resolution of the display panel might cause a problem of weak sense of reality and immersion.

The display panel is also required to have high color reproducibility. In particular, when using the display panel with high color reproducibility, the above-described device for VR, AR, SR, or MR can perform display with colors that are close to the actual object color, leading to higher sense of reality and immersion.

An object of one embodiment of the present invention is to provide a display device with extremely high resolution. An object of one embodiment of the present invention is to provide a display device in which high color reproducibility is achieved. An object of one embodiment of the present invention is to provide a high-luminance display device. An object of one embodiment of the present invention is to provide a highly reliable display device. Another object of one embodiment of the present invention is to provide a method for manufacturing the above-described display device.

Note that the descriptions of these objects do not disturb the existence of other objects.

One embodiment of the present invention does not have to achieve all the objects. Note that objects other than these can be derived from the descriptions of the specification, the drawings, the claims, and the like.

### Means for Solving the Problems

One embodiment of the present invention is a method for manufacturing a display device, in which a first conductor is formed; a first insulator is formed over the first conductor; an opening reaching the first conductor is provided in the first insulator; a second conductor is formed inside the opening and over the first insulator; a third conductor is formed by removing part of the second conductor to expose a top surface of the first insulator; a first light-emitting layer is formed over the third conductor and the first insulator; a fourth conductor is formed over the first light-emitting layer; and a fifth conductor is formed by removing part of the fourth conductor.

In the above structure, the second conductor preferably includes a first region in contact with the inside of the opening and a second region in contact with the first insulator.

In the above structure, formation of the fifth conductor is preferably performed by formation of a resist mask over the fourth conductor and etching using the resist mask.

In the above structure, the third conductor is preferably formed by removing part of the second conductor by chemical mechanical polishing to expose the top surface of the first insulator.

In the above structure, a top surface of the third conductor and the top surface of the first insulator are preferably substantially aligned with each other.

In the above structure, the third conductor preferably has a function of reflecting visible light, and the fifth conductor preferably has a function of transmitting visible light.

Another embodiment of the present invention is a method for manufacturing a display device, in which a first conductor, a second conductor, and a third conductor are formed; a first insulator is formed over the first conductor, over the second conductor, and over the third conductor; a first opening reaching the first conductor, a second opening reaching the second conductor, and a third opening reaching the third conductor are provided in the first insulator; a fourth conductor is formed inside the first opening, inside the second opening, inside the third opening, and over the first insulator; part of the fourth conductor is removed to expose a top surface of the first insulator; a fifth conductor over the first conductor, a sixth conductor over the second conductor, and a seventh conductor over the third conductor are formed; a first light-emitting layer is formed over the fifth conductor, over the sixth conductor, over the seventh conductor, and over the first insulator; part of the first light-emitting layer is removed to form a second light-emitting layer over the fifth conductor; a third light-emitting layer is formed over the fifth conductor, over the sixth conductor, over the seventh conductor, over the first insulator, and over the second light-emitting layer; part of the third light-emitting layer is removed to form a fourth light-emitting layer over the sixth conductor; a fifth light-emitting layer is formed over the fifth conductor, over the sixth conductor, over the seventh conductor, over the first insulator, over the second light-emitting layer, and over the fourth light-emitting layer; and part of the fifth light-emitting layer is removed to form a sixth light-emitting layer over the seventh conductor.

In the above structure, the second light-emitting layer preferably contains a light-emitting substance emitting blue light, the fourth light-emitting layer preferably contains a light-emitting substance emitting green light, and the sixth light-emitting layer preferably contains a light-emitting substance emitting red light.

In the above structure, formation of the second light-emitting layer is preferably performed by formation of a first resist mask over the first light-emitting layer and etching using the first resist mask; formation of the fourth light-emitting layer is preferably performed by formation of a second resist mask over the third light-emitting layer and etching using the second resist mask; and formation of the sixth light-emitting layer is preferably performed by formation of a third resist mask over the fifth light-emitting layer and etching using the third resist mask.

In the above structure, the fifth conductor, the sixth conductor, and the seventh conductor are preferably formed by removing part of the fourth conductor by chemical mechanical polishing to expose the top surface of the first insulator.

In the above structure, a top surface of the fifth conductor, a top surface of the sixth conductor, a top surface of the seventh conductor, and the top surface of the first insulator are preferably substantially level with each other.

Another embodiment of the present invention is a display device, including a first conductor, a first insulator over the first conductor, a second conductor provided inside an opening of the first insulator, a first light-emitting layer in contact with a top surface of the second conductor and a top surface of the first insulator, and a third conductor in contact with a top surface of the first light-emitting layer.

In the above structure, the first conductor and the second conductor are preferably electrically connected to each other.

In the above structure, the second conductor preferably includes a region in contact with a sidewall of the opening.

In the above structure, the top surface of the second conductor and the top surface of the first insulator are preferably substantially level with each other.

### Effect of the Invention

According to one embodiment of the present invention, a display device with extremely high resolution can be provided. A display device in which high color reproducibility is achieved can be provided. A high-luminance display device can be provided. A highly reliable display device can be provided. A method for manufacturing the above-described display device can be provided.

Note that the descriptions of the effects do not disturb the existence of other effects. Note that one embodiment of the present invention does not need to have all these effects. Note that effects other than these can be derived from the descriptions of the specification, the drawings, the claims, and the like.

### BRIEF DESCRIPTION OF THE DRAWINGS

FIG. 1A to FIG. 1D are diagrams illustrating a structure example of a display device.

FIG. 2A and FIG. 2B are diagrams illustrating a structure example of a display device.

FIG. 3A to FIG. 3C are diagrams illustrating a structure example of a display device.

FIG. 4A to FIG. 4D are diagrams illustrating a structure example of a display device.

FIG. 5A to FIG. 5E are diagrams illustrating an example of a method for manufacturing a display device.

FIG. 6A to FIG. 6E are diagrams illustrating an example of a method for manufacturing a display device.

FIG. 7 is a diagram illustrating a structure example of a display device.

FIG. 8 is a diagram illustrating a structure example of a display device.

FIG. 9 is a diagram illustrating a structure example of a display device.

FIG. 10 is a diagram illustrating a structure example of a display device.

FIG. 11A and FIG. 11B are diagrams illustrating a structure example of a display module.

FIG. 12A and FIG. 12B are circuit diagrams illustrating an example of a display device.

FIG. 13A and FIG. 13C are circuit diagrams each illustrating an example of a display device.

FIG. 13B is a timing chart showing an operation example of a display device.

FIG. 14A and FIG. 14B are diagrams illustrating a structure example of an electronic device.

FIG. 15A and FIG. 15B are diagrams illustrating a structure example of an electronic device.

FIG. 16A to FIG. 16C are diagrams illustrating a structure example of a display device.

FIG. 17 is a diagram illustrating a structure example of a display device.

FIG. 18 is a diagram illustrating a structure example of a display device.

FIG. 19 is a diagram illustrating a structure example of a display device.

FIG. 20 is a diagram illustrating a structure example of a display device.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, ordinal numbers such as “first,” “second,” and the like are used in order to avoid confusion among components and do not limit the number.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. In this specification and the like, a light-emitting device capable of emitting white light may be referred to as a white-light-emitting device. Note that a white-light-emitting device that is combined with coloring layers (e.g., color filters) can be a light-emitting device of full-color display.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more light-emitting layers are selected such that their emission colors are complementary. For example, when emission color of a first light-emitting layer and emission color of a second light-emitting layer are complementary colors, the light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the case of a single structure. In the device having a tandem structure, it is suitable that an intermediate layer such as a charge-generation layer is provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is suitably used. Meanwhile, the white-light-emitting device is suitable in terms of lower manufacturing cost or higher manufacturing yield because the manufacturing process of the white-light-emitting device is simpler than that of a light-emitting device having an SBS structure.

### Embodiment 1

In this embodiment, a display device of one embodiment of the present invention and a manufacturing method of the display device will be described.

The display device of one embodiment of the present invention includes light-emitting elements (also referred to as light-emitting devices) emitting light of different colors. The light-emitting element includes a lower electrode, an upper electrode, and a light-emitting layer (also referred to as a layer containing a light-emitting compound) therebetween. As the light-emitting element, an electroluminescent element such as an organic EL element or an inorganic EL element is preferably used. Alternatively, a light-emitting diode (LED) may be used.

As the EL element, an OLED (Organic Light Emitting Diode), a QLED (Quantum-dot Light Emitting Diode), or the like can be used. As a light-emitting compound (also referred to as a light-emitting substance) contained in the EL element, a substance that exhibits fluorescence (a fluorescent material), a substance that exhibits phosphorescence (a phosphorescent material), an inorganic compound (e.g., a quantum dot material), a substance that exhibits thermally activated delayed fluorescence (a thermally activated delayed fluorescent (TADF) material), and the like can be given.

As the light-emitting substance, a substance that exhibits an emission color of blue, purple, bluish purple, green, yellowish green, yellow, orange, red, or the like is appropriately used.

A substance that emits near-infrared light may also be used.

The light-emitting layer may contain one or more kinds of compounds (e.g., a host material and an assist material) in addition to the light-emitting substance (a guest material). As the host material and the assist material, one or more kinds of substances whose energy gap is larger than the energy gap of the light-emitting substance (the guest material) can be selected and used. As the host material and the assist material, compounds which form an exciplex are preferably used in combination. In order to form an exciplex efficiently, it is particularly preferable to combine a compound that easily accepts holes (a hole-transport material) and a compound that easily accepts electrons (an electron-transport material).

Either a low molecular compound or a high molecular compound can be used for the light-emitting element, and an inorganic compound (e.g., a quantum dot material) may also be contained.

In the display device of one embodiment of the present invention, the light-emitting elements of different colors can be separately formed with extremely high accuracy. Thus, a display device with higher resolution than a conventional display device can be achieved. For example, the display device preferably has extremely high resolution in which pixels including one or more light-emitting elements are arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

More specific structure examples and manufacturing method examples will be described below with reference to drawings.

### Structure Example 1

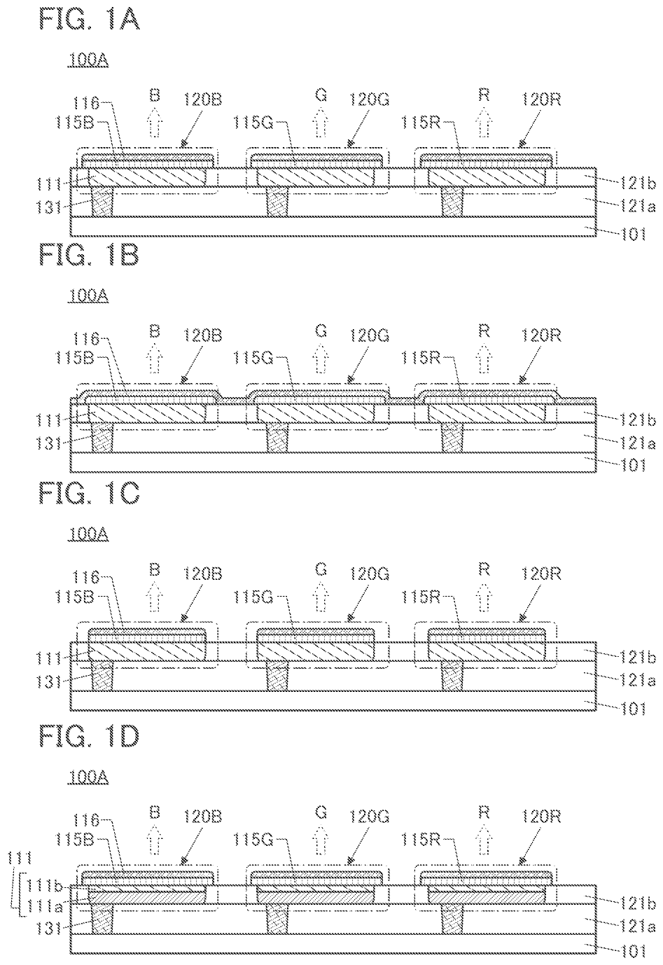

FIG. 1A is a schematic cross-sectional view illustrating a display device of one embodiment of the present invention. A display device 100A includes a light-emitting element 120R, a light-emitting element 120G, and a light-emitting element 120B. The light-emitting element 120R is a light-emitting element emitting red light, the light-emitting element 120G is a light-emitting element emitting green light, and the light-emitting element 120B is a light-emitting element emitting blue light.

Note that in the following description common to the light-emitting element 120R, the light-emitting element 120G, and the light-emitting element 120B, the alphabets applied to the reference numerals are omitted and the term “light-emitting element 120” is used in some cases.

In a similar manner, an EL layer 115R, an EL layer 115G, and an EL layer 115B, which are described later, are described using the term “EL layer 115” in some cases. The EL layer 115R is included in the light-emitting element 120R. In a similar manner, the EL layer 115G and the EL layer 115B are included in the light-emitting element 120G and the light-emitting element 120B, respectively. Similarly, a conductive layer 114R, a conductive layer 114G, and a conductive layer 114B, which are described later, are described using the term “conductive layer 114” in some cases. The conductive layer 114R is included in the light-emitting element 120R. In a similar manner, the conductive layer 114G and the conductive layer 114B are included in the light-emitting element 120G and the light-emitting element 120B, respectively.

The light-emitting element 120 includes a conductive layer 111 functioning as a lower electrode, the EL layer 115, and a conductive layer 116 functioning as an upper electrode. The conductive layer 111 has a reflective property with respect to visible light. The conductive layer 116 has a transmissive property and a reflective property with respect to visible light. The EL layer 115 includes alight-emitting compound. The EL layer 115 includes at least alight-emitting layer included in the light-emitting element 120.

The conductive layer 116 has a transmissive property and a reflective property with respect to visible light.

As the light-emitting element 120, it is possible to use an electroluminescent element having a function of emitting light in accordance with current flowing into the EL layer 115 when a potential difference is supplied between the conductive layer 111 and the conductive layer 116. In particular, an organic EL element using a light-emitting organic compound is preferably used for the EL layer 115. The light-emitting element 120 is an element emitting light of blue, purple, bluish purple, green, yellowish green, yellow, orange, red, or the like, for example. Alternatively, for example, the light-emitting element 120 is an element emitting white light, which has two or more peaks in the visible light region of the emission spectrum.

The conductive layer 111 has a reflective property with respect to visible light.

The display device 100A includes a substrate 101 provided with a semiconductor circuit and the light-emitting element 120 over the substrate 101. The display device 100A illustrated in FIG. TA includes an insulating layer 121a over the substrate 101, an insulating layer 121b over the insulating layer 121a, and the light-emitting element 120 over the insulating layer 121b.

The substrate 101 can use a circuit substrate including one or more of a transistor, a wiring, and the like. Note that in the case of either a passive matrix method or a segment method can be employed, an insulating substrate such as a glass substrate can be used as the substrate 101. The substrate 101 is a substrate provided with one or more of a circuit for driving the light-emitting elements (also referred to as a pixel circuit) and a semiconductor circuit functioning as a driver circuit for driving the pixel circuit. More specific structure examples of the substrate 101 will be described later.

In the display device 100A illustrated in FIG. TA, the substrate 101 and the conductive layer 111 of the light-emitting element 120 are electrically connected to each other through a plug 131. The plug 131 is formed to be embedded in an opening provided in the insulating layer 121a. The conductive layer 111 is formed to be embedded in an opening provided in the insulating layer 121b. The conductive layer 111 is provided over the plug 131. The conductive layer 111 and the plug 131 are electrically connected to each other. The conductive layer 111 is preferably in contact with a top surface of the plug 131.

In the display device of one embodiment of the present invention, the conductive layer functioning as a lower electrode of the light-emitting element is formed to be embedded in the opening of the insulating layer, whereby the EL layer can be formed over a flat surface.

In the case where a conductive layer is formed over an insulating layer, unevenness is caused by the conductive layer. In such a case, the thickness of an EL layer is reduced in some cases when end portions of the conductive layer are covered.

When the thickness of the EL layer that coats the end portions of the conductive layer is thin, the upper electrode and the lower electrode of the light-emitting element may be short-circuited to decrease the yield of the display device. Such a short circuit can be inhibited by providing an insulator covering the end portions of the conductive layer (referred to as a bank, a partition, a barrier, an embankment, or the like in some cases).

However, the distance between adjacent light-emitting elements becomes large when the insulator is provided between the adjacent light-emitting elements; thus, miniaturization might be difficult.

In the display device of one embodiment of the present invention, the EL layer can be formed over the flat surface; thus, a structure in which an insulator covering end portions of the conductive layer is not included can be provided.

An etching residue may be deposited in a depressed portion generated by a step of the conductive layer. Such a residue might lead a failure such as a short circuit, resulting in the decrease in yield of the display device. The use of the structure of the display device of one embodiment of the present invention can inhibit a failure in processing the EL layer and processing the upper electrode in the manufacturing process of the light-emitting element. Thus, the yield of the display device can be increased.

The display device of one embodiment of the present invention can be miniaturized with a high yield.

In the display device 100A illustrated in FIG. TA, the EL layer 115 and the conductive layer 116 are each separated between adjacent light-emitting elements of different colors. Accordingly, leakage current flowing through the EL layer 115 between the adjacent light-emitting elements of different colors can be prevented. Thus, light emission caused by the leakage current can be inhibited, so that display with high contrast can be obtained. Furthermore, even in the case where the resolution is increased, the range of choices for materials can be widened since the EL layer 115 can be formed using a material with high conductivity, which facilitates an improvement in efficiency, a reduction in power consumption, and an improvement in reliability.

Note that in the display device 100A, the EL layer 115 and the conductive layer 116 are preferably processed to be not separated but continuous between pixels exhibiting the same color. For example, the EL layer 115 and the conductive layer 116 can be processed into a stripe shape. Thus, the conductive layer 116 of all the light-emitting elements can be supplied with a predetermined potential without being in a floating state.

The EL layer 115 and the conductive layer 116 may be patterned into an island shape by deposition with the use of a shadow mask such as a metal mask; however, it is particularly preferable to employ a processing method using no metal mask. Accordingly, an extremely minute pattern can be formed; thus, resolution and the aperture ratio can be improved as compared to the formation method using a metal mask. A typical example of such a processing method is a photolithography method. Alternatively, a formation method such as a nanoimprinting method, a sandblasting method, or the like can be used.

In a cross section of the display device 100A illustrated in FIG. TA, end portions of the EL layer 115 are positioned outward from end portions of the conductive layer 111. When the end portions of the EL layer 115 are positioned outward from the end portions of the conductive layer 111, a short circuit between the conductive layer 111 and the conductive layer 116 can be inhibited. In the cross section of the display device 100A illustrated in FIG. TA, end portions of the conductive layer 116 are positioned outward from the end portions of the conductive layer 111.

In the cross section of the display device 100A illustrated in FIG. TA, the end portions of the EL layer 115 and the end portions of the conductive layer 116 are substantially aligned with each other.

In the display device 100A illustrated in FIG. 1B, the conductive layer 116 is shared by the light-emitting element 120R, the light-emitting element 120G, and the light-emitting element 120B. The conductive layer 116 functions as, for example, an electrode to which a common potential is supplied. Providing the conductive layer 116 to be shared by the light-emitting elements is preferable because the manufacturing process of the light-emitting element 120 can be reduced. A potential for controlling the amount of light emitted from the light-emitting element 120 is independently supplied to the conductive layer 111 provided in the light-emitting elements 120. The conductive layer 111 functions as a pixel electrode, for example.

In a cross section of the display device 100A illustrated in FIG. 1B, the conductive layer 116 covers end portions of the EL layer 115B, end portions of the EL layer 115G, and end portions of the EL layer 115R.

As illustrated in FIG. 1C, the end portions of the EL layer 115 may be substantially aligned with the end portions of the conductive layer 111. Alternatively, one of the end portions of the EL layer 115 may be positioned outward from the conductive layer 111 and the other of the end portions of the EL layer 115 may be substantially aligned with the end portion of the conductive layer 111. The end portions of the EL layer 115 may be positioned inward from the end portions of the conductive layer 111.

### [Light-Emitting Element]

As a light-emitting element that can be used as the light-emitting element 120, a self-luminous element can be used, and an element whose luminance is controlled by current or voltage is included in the category. For example, an LED, an organic EL element, an inorganic EL element, or the like can be used. In particular, an organic EL element is preferably used.

The light-emitting element has a top-emission structure, a bottom-emission structure, a dual-emission structure, or the like. A conductive film that transmits visible light is used as the electrode through which light is extracted. A conductive film that reflects visible light is preferably used as the electrode through which no light is extracted.

In one embodiment of the present invention, in particular, a top-emission light-emitting element in which light is emitted toward the side opposite to the formation surface side or a dual-emission light-emitting element in which light is emitted toward both the formation surface side and the side opposite to the formation surface side can be preferably used.

The EL layer 115 includes at least a light-emitting layer. In addition to the light-emitting layer, the EL layer 115 may further include layers containing a substance with a high hole-injection property, a substance with a high hole-transport property, a hole-blocking material, a substance with a high electron-transport property, a substance with a high electron-injection property, a substance with a bipolar property (a substance with a high electron-transport property and a high hole-transport property), and the like.

Either a low molecular compound or a high molecular compound can be used for the EL layer 115, and an inorganic compound may also be contained. The layers that constitute the EL layer 115 can each be formed by a method such as an evaporation method (including a vacuum evaporation method), a transfer method, a printing method, an inkjet method, or a coating method.

When a voltage higher than the threshold voltage of the light-emitting element 120 is applied between a cathode and an anode, holes are injected to the EL layer 115 from the anode side and electrons are injected to the EL layer 115 from the cathode side. The injected electrons and holes are recombined in the EL layer 115 and a light-emitting substance contained in the EL layer 115 emits light.

Here, the EL layer 115 used for the light-emitting element 120B, the EL layer 115 used for the light-emitting element 120G, and the EL layer 115 used for the light-emitting element 120R can be represented as the EL layer 115B, the EL layer 115G, and the EL layer 115R, respectively. The EL layer 115B contains a light-emitting substance emitting B (blue) light. The EL layer 115G contains a light-emitting substance emitting G (green) light. The EL layer 115R contains alight-emitting substance emitting R (red) light. Such a structure in which emission colors (here, blue (B), green (G), and red (R)) are separately patterned for each of the light-emitting elements is referred to as a side-by-side (SBS) structure in some cases.

A visible-light-transmitting conductive film that can be used for the conductive layer 114 or the like described later can be formed using, for example, indium oxide, indium tin oxide, indium zinc oxide, zinc oxide, or zinc oxide to which gallium is added. Alternatively, a metal material such as gold, silver, platinum, magnesium, nickel, tungsten, chromium, molybdenum, iron, cobalt, copper, palladium, or titanium; an alloy containing any of these metal materials; a nitride of any of these metal materials (e.g., titanium nitride); or the like formed thin enough to have a light-transmitting property can be used. A stacked-layer film of any of the above materials can be used for the conductive layer. For example, a stacked-layer film of indium tin oxide and an alloy of silver and magnesium is preferably used, in which case conductivity can be increased.

Further alternatively, graphene or the like may be used.

For a portion of the conductive layer 111 positioned on the EL layer 115 side, a conductive film that reflects the visible light is preferably used. For the conductive layer 111, for example, a metal material such as aluminum, gold, platinum, silver, nickel, tungsten, chromium, molybdenum, iron, cobalt, copper, or palladium or an alloy containing any of these metal materials can be used. Copper is preferable because of its high reflectance of visible light. In addition, aluminum is preferable because an aluminum electrode is easily etched and thus is easily processed and aluminum has high reflectance of visible light and near-infrared light. Lanthanum, neodymium, germanium, or the like may be added to each of the above metal materials and the alloy. Alternatively, an alloy (an aluminum alloy) containing aluminum and titanium, nickel, or neodymium may be used. Alternatively, an alloy containing silver and copper, palladium, or magnesium may be used. An alloy containing silver and copper is preferable because of its high heat resistance.

For the conductive layer 111, a structure may be employed in which a conductive metal oxide film is stacked over a conductive film that reflects visible light. Such a structure can inhibit oxidation or corrosion of the conductive film that reflects visible light. For example, when a metal film or a metal oxide film is stacked in contact with an aluminum film or an aluminum alloy film, oxidation can be inhibited. As examples of a material for the metal film and the metal oxide film, titanium and titanium oxide can be given, respectively. Alternatively, the above conductive film that transmits visible light and a film containing a metal material may be stacked. For example, a stacked-layer film of silver and indium tin oxide or a stacked-layer film of an alloy of silver and magnesium and indium tin oxide can be used.

In the conductive layer 111, a conductive layer 111a may be provided as a lower conductive layer, and a conductive layer 111b may be provided over the conductive layer 111a as an upper conductive layer as illustrated in FIG. 1D. In such a structure, a conductive film that reflects visible light is preferably used as the conductive layer 111b. The reflectance of the conductive layer 111a may be lower than that of the conductive layer 111b. A material with high conductivity may be used for the conductive layer 111a. A material having an excellent processability may be used for the conductive layer 111a.

The above-described materials and structures that can be used for the conductive layer 111 are preferably used for the conductive layer 111b. For the conductive layer 111a, for example, a metal material such as gold, silver, platinum, magnesium, nickel, tungsten, chromium, molybdenum, iron, cobalt, copper, palladium, titanium, yttrium, zirconium, or tantalum; an alloy containing any of these metal materials; or a nitride of any of these metal materials (e.g., titanium nitride) can be used.

When aluminum is used for the conductive layer 111 or the conductive layer 111b, the thickness of aluminum is preferably greater than or equal to 40 nm, further preferably greater than or equal to 70 nm, in which case the reflectance of visible light or the like can be sufficiently increased. When silver is used for the conductive layer 111 or the conductive layer 111b, the thickness of silver is preferably greater than or equal to 70 nm, further preferably greater than or equal to 100 nm, in which case the reflectance of visible light or the like can be sufficiently increased.

As an example, tungsten can be used for the conductive layer 111a and aluminum or an aluminum alloy can be used for the conductive layer 111b. The conductive layer 111b may have a structure in which titanium oxide is provided in contact with an upper portion of aluminum or an aluminum alloy. Alternatively, the conductive layer 111b may have a structure in which titanium is provided in contact with an upper portion of aluminum or an aluminum alloy, and titanium oxide is provided in contact with an upper portion of titanium.

Alternatively, a material and a structure selected from the above-described materials and structures that can be used for the conductive layer 111 may be used for the conductive layer 111a and the conductive layer 111b.

Alternatively, the conductive layer 111 may have a stacked-layer structure of three or more layers.

Examples of a material that can be used for the plug 131 include metals such as aluminum, titanium, chromium, nickel, copper, yttrium, zirconium, molybdenum, gold, silver, platinum, magnesium, iron, cobalt, palladium, tantalum, and tungsten; an alloy containing any of these metal materials; and a nitride of any of these metal materials. As the plug 131, a single layer or stacked-layer structure including a film containing any of these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Copper containing manganese is preferably used because it increases controllability of a shape by etching.

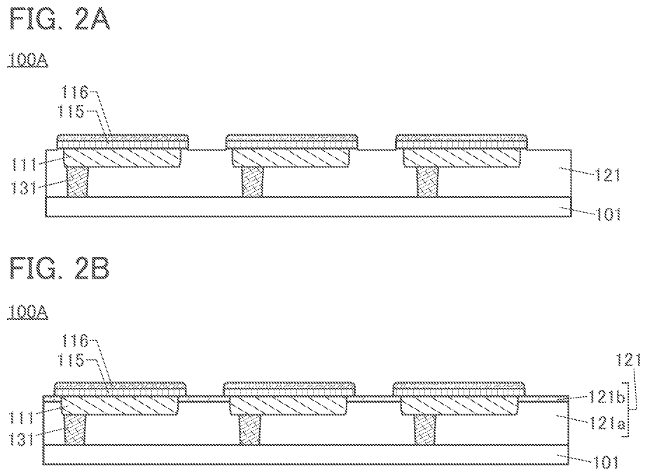

In the insulating layer 121, a depressed portion may be formed in a surface where the EL layer 115 or the conductive layer 116 is not provided as illustrated in FIG. 2A. For example, a depressed portion is formed by etching of the insulating layer 121 in the etching step at the time of forming the EL layer 115 and at the time of forming the conductive layer 116.

As illustrated in FIG. 2B, the insulating layer 121 has a stacked-layer structure including the insulating layer 121a and the insulating layer 121b, and the insulating layer 121b is formed using a material having a low etching rate in the etching at the time of forming the EL layer 115 and at the time of forming the conductive layer 116; thus, formation of a depressed portion may be inhibited. In FIG. 2B, the insulating layer 121b is positioned over the insulating layer 121a. As the insulating layer 121b, for example, hafnium oxide or aluminum oxide can be used.

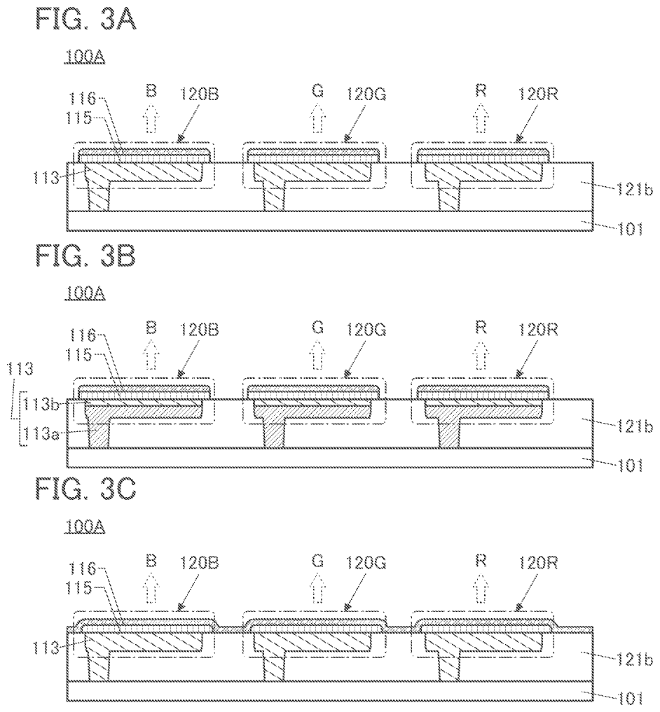

As illustrated in FIG. 3A, a conductive layer 113 serving as both the conductive layer 111 and the plug 131 may be provided. As illustrated in FIG. 3B, the conductive layer 113 may have a stacked-layer structure of a conductive layer 113a and a conductive layer 113b over the conductive layer 113a. The conductive layer 113 and the conductive layer 113a can be formed by a dual damascene method. The use of the dual damascene method enables the formation of the plugs and the formation of the conductive layer to be performed together; thus, the process can be simplified. Note that in the structures illustrated in FIG. 3A and FIG. 3B, either the insulating layer 121a or the insulating layer 121b is not necessarily provided, and the conductive layer 113 may be embedded in only one of the insulating layers. A structure in which the conductive layer 113 is embedded in the insulating layer 121b is illustrated in FIG. 3A and FIG. 3B. As illustrated in FIG. 3C, the conductive layer 116 may be shared by the light-emitting element 120B, the light-emitting element 120G, and the light-emitting element 120R.

The materials used for the conductive layer 111 and the plug 131 can be referred to for materials that can be used for the conductive layer 113, the conductive layer 113a, and the conductive layer 113b. A conductive film that reflects visible light is preferably used for the conductive layer 113 and the conductive layer 113a. For example, copper can be used for the conductive layer 113 and the conductive layer 113a.

As the conductive film having a transmissive property and a reflective property that can be used for the conductive layer 116, the conductive film reflecting visible light formed to be thin enough to transmit visible light can be used. In addition, with the stacked-layer structure of the conductive film and the conductive film transmitting visible light, the conductivity and the mechanical strength can be increased.

The conductive film having a semi-transmissive property and a semi-reflective property preferably has a reflectance with respect to visible light (e.g., the reflectance with respect to light having a certain wavelength within the range of 400 nm to 700 nm) of higher than or equal to 20% and lower than or equal to 80%, further preferably higher than or equal to 40% and lower than or equal to 70%. The conductive film having a reflective property preferably has a reflectance with respect to visible light of higher than or equal to 40% and lower than or equal to 10000, further preferably higher than or equal to 70% and lower than or equal to 100%. The conductive film having a light-transmitting property preferably has a reflectance with respect to visible light of higher than or equal to 0% and lower than or equal to 40%, further preferably higher than or equal to 0% and lower than or equal to 30%.

The electrodes constituting the light-emitting elements may each be formed by an evaporation method or a sputtering method. Alternatively, a discharging method such as an inkjet method, a printing method such as a screen printing method, or a plating method may be used for the formation.

Note that the aforementioned light-emitting layer and layers containing a substance with a high hole-injection property, a substance with a high hole-transport property, a substance with a high electron-transport property, a substance with a high electron-injection property, a substance with a bipolar property, and the like may include an inorganic compound such as a quantum dot or a high molecular compound (e.g., an oligomer, a dendrimer, and a polymer). For example, when used for the light-emitting layer, the quantum dots can function as a light-emitting material.

Note that as the quantum dot material, a colloidal quantum dot material, an alloyed quantum dot material, a core-shell quantum dot material, a core quantum dot material, or the like can be used. A material containing elements belonging to Group 12 and Group 16, elements belonging to Group 13 and Group 15, or elements belonging to Group 14 and Group 16, may be used. Alternatively, a quantum dot material containing an element such as cadmium, selenium, zinc, sulfur, phosphorus, indium, tellurium, lead, gallium, arsenic, or aluminum may be used.

As the EL layer 115 included in the light-emitting element 120, a light-emitting substance that emits white light may be used. In the case where a light-emitting substance emitting white light is used for the EL layer 115, the EL layer 115 preferably contains two or more kinds of light-emitting substances. A white emission can be obtained by selecting light-emitting substances so that two or more light-emitting substances emit light of complementary colors, for example. For example, it is preferable to contain two or more out of light-emitting substances emitting light of R (red), G (green), B (blue), Y (yellow), O (orange), and the like or light-emitting substances emitting light containing two or more of spectral components of R, G, and B. A light-emitting element whose emission spectrum has two or more peaks in the wavelength range of a visible light region (e.g., 350 nm to 750 nm) is preferably employed. An emission spectrum of a material having a peak in a yellow wavelength range preferably has spectral components also in green and red wavelength ranges.

The EL layer 115 can have a structure in which a light-emitting layer containing a light-emitting material emitting light of one color and a light-emitting layer containing a light-emitting material emitting light of another color are stacked. For example, the plurality of light-emitting layers in the EL layer 115 may be stacked in contact with each other or may be stacked with a region not including any light-emitting material therebetween. For example, between a fluorescent layer and a phosphorescent layer, a region that contains the same material as the fluorescent layer or phosphorescent layer (for example, a host material or an assist material) and no light-emitting material may be provided. This facilitates the manufacturing of the light-emitting element and reduces the drive voltage.

The light-emitting element 120 may be a single element including one EL layer or a tandem element in which a plurality of EL layers are stacked with a charge-generation layer therebetween.

In the light-emitting element 120, the conductive layer 114 may be provided between the conductive layer 111 and the EL layer 115. The conductive layer 114 has a function of transmitting visible light.

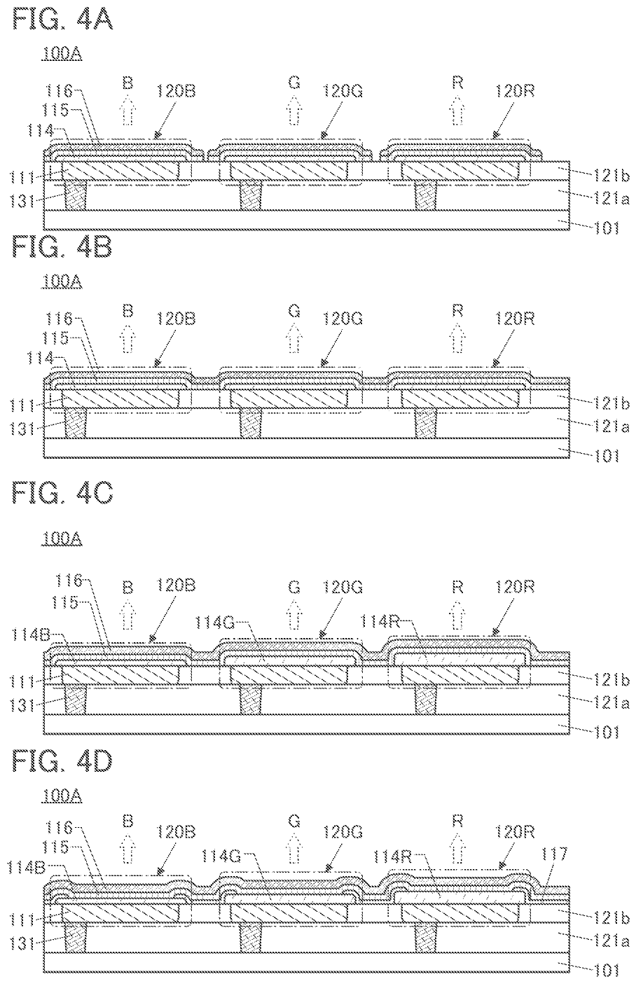

The conductive layer 114 provided in each of the light-emitting elements 120 that are included in the display device 100A illustrated in FIG. 4A is placed between the conductive layer 111 and the EL layer 115. The conductive layer 114 is positioned over the conductive layer 111. The conductive layer 114 includes a region positioned over the insulating layer 121b. The EL layer 115 is preferably provided to cover end portions of the conductive layer 114.

As illustrated in FIG. 4B, the EL layer 115 may be shared by each of the light-emitting elements 120. In FIG. 4B, the continuous EL layer 115 is provided so as to cover the conductive layer 114 of each of the light-emitting elements 120.

As illustrated in FIG. 4C, the conductive layer 114 provided in each of the light-emitting elements 120 preferably has a thickness that differs among the light-emitting elements. Among the three conductive layers 114, the thickness of the conductive layer 114B is the smallest, and the thickness of the conductive layer 114R is the largest. Here, the distance between atop surface of the conductive layer 111 and a bottom surface of the conductive layer 116 (i.e., the interface between the conductive layer 116 and the EL layer 115) in each of the light-emitting elements is the largest in the light-emitting element 120R and the smallest in the light-emitting element 120B. In each of the light-emitting elements, the distance between the top surface of the conductive layer 111 and the bottom surface of the conductive layer 116 is changed, whereby the optical distance (optical path length) in each of the light-emitting elements can be changed.

The light-emitting element 120R has the longest optical path length among the three light-emitting elements, and thus emits light R that is the intensified light with the longest wavelength. In contrast, the light-emitting element 120B has the shortest optical path length, and thus emits light B that is the intensified light with the shortest wavelength. The light-emitting element 120G emits light G that is the intensified light with the intermediate wavelength. For example, the light R is the intensified red light, the light G is the intensified green light, and the light B is the intensified blue light.

With such a structure, the EL layer included in the light-emitting element 120 need not be formed separately for different colors of the light-emitting elements; thus, color display with high color reproducibility can be performed using elements with the same structure. In addition, the light-emitting elements 120 can be arranged extremely densely. For example, a display device having resolution exceeding 5000 ppi can be achieved.

In each of the light-emitting elements, the optical distance between the surface of the conductive layer 111 reflecting visible light and the conductive layer 116 having a semi-transmissive property and a semi-reflective property with respect to visible light is preferably adjusted to be mλ/2 (m is a positive integer) or in the vicinity thereof, where λ is the wavelength of light whose intensity is desired to be increased.

To be exact, the above-described optical distance depends on a product of the physical distance between a reflective surface of the conductive layer 111 and a reflective surface of the conductive layer 116 having a semi-transmissive property and a semi-reflective property and the refractive index of a layer provided therebetween, and thus is difficult to adjust exactly. Thus, it is preferable to adjust the optical distance on the assumption that the surface of the conductive layer 111 and the surface of the conductive layer 116 having a semi-transmissive property and a semi-reflective property are each the reflective surface.

As described later, the color purity of light from the light-emitting element can be improved by providing a coloring layer 165 overlapping with the light-emitting element 120.

As illustrated in FIG. 4D, an insulator 117 covering the end portions of the conductive layer 114 may be provided.

The light-emitting element 120 may have a structure in which a plurality of EL layers are stacked.

The EL layer included in the light-emitting element 120 may have a structure in which a plurality of EL layers are stacked. For example, the EL layer 115 has a structure in which an EL layer containing a light-emitting substance emitting blue light, an EL layer containing a light-emitting substance emitting green light, and an EL layer containing a light-emitting substance emitting red light are stacked. In addition to the layer containing a light-emitting compound, each of the EL layers may include an electron-injection layer, an electron-transport layer, a charge-generation layer, a hole-transport layer, a hole-injection layer, and the like. Note that a charge-generation layer may be provided between the EL layer 115B and the EL layer 115G. A charge-generation layer may be provided between the EL layer 115G and the EL layer 115R.

### <Structure Example of EL Layer>

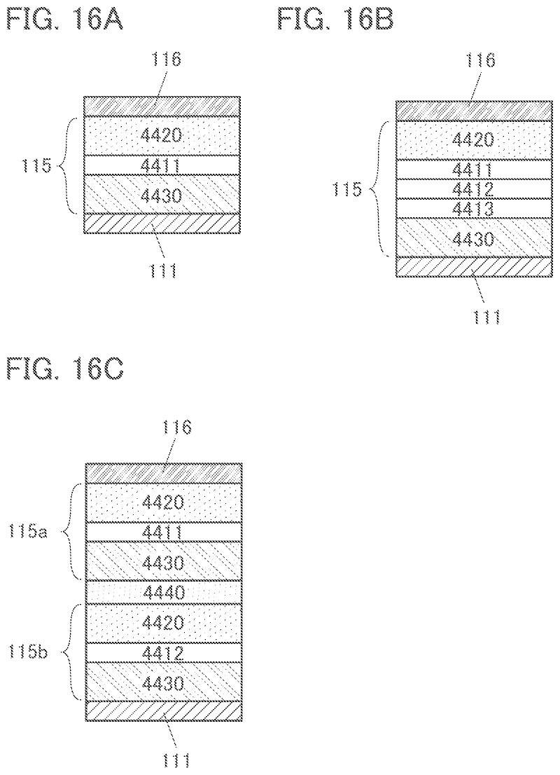

The EL layer 115 included in the light-emitting element 120 can be formed of a plurality of layers such as a layer 4420, a light-emitting layer 4411, and a layer 4430, as illustrated in FIG. 16A. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can serve as a single light-emitting unit, and the structure in FIG. 16A is referred to as a single structure in this specification.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 16B is another variation of the single structure.

The structure in which a plurality of light-emitting units (an EL layer 115a and an EL layer 115b) are connected in series with an intermediate layer (charge-generation layer) 4440 therebetween as illustrated in FIG. 16C is referred to as a tandem structure in this specification. In this specification and the like, the structure illustrated in FIG. 16C is referred to as a tandem structure; however, without being limited to this, a tandem structure may be referred to as a stack structure, for example. The tandem structure enables a light-emitting element capable of high luminance light emission.

The emission color of the light-emitting element 120 can be red, green, blue, cyan, magenta, yellow, white, or the like depending on the material that constitutes the EL layer 115.

Furthermore, the color purity can be further increased when the light-emitting element 120 has a microcavity structure.

In the case where the emission color of the light-emitting element 120 is white, the light-emitting layer preferably contains two or more kinds of light-emitting substances. To obtain white light emission, two or more kinds of light-emitting substances are selected such that their emission colors are complementary. For example, the light-emitting layer preferably contains two or more selected from light-emitting substances that emit light of red, green, blue, yellow, orange, and the like. Alternatively, the light-emitting layer preferably contains two or more light-emitting substances that emit light containing two or more of spectral components of red, green, and blue.

### Manufacturing Method Example 1

An example of a manufacturing method of the display device of one embodiment of the present invention will be described with reference to drawings.

An example of a manufacturing method of the display device of one embodiment of the present invention will be described with reference to drawings.

Note that thin films that constitute the display device (insulating films, semiconductor films, conductive films, or the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. In addition, as an example of the thermal CVD method, a metal organic chemical vapor deposition (MOCVD) method can be given.

Alternatively, thin films that constitute the display device (insulating films, semiconductor films, conductive films, or the like) can be formed by a method such as spin coating, dipping, spray coating, ink-jetting, dispensing, screen printing, offset printing, a doctor knife, a slit coater, a roll coater, a curtain coater, and a knife coater.

When the thin films that constitute the light-emitting device are processed, a photolithography method or the like can be used for the processing. Besides, a nanoimprinting method, a sandblasting method, a lift-off method, or the like may be used for the processing of the thin films. Island-shaped thin films may be directly formed by a film formation method using a blocking mask such as a metal mask.

There are two typical examples of a photolithography method. In one of the methods, a resist mask is formed over a thin film that is to be processed, and the thin film is processed by etching or the like, and then, the resist mask is removed. In the other method, after a photosensitive thin film is formed, exposure and development are performed, and then, the thin film is processed into a desired shape.

For light for exposure in a photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Furthermore, exposure may be performed by liquid immersion light exposure technique. As the light used for the exposure, extreme ultraviolet (EUV) light or X-rays may be used. Furthermore, instead of the light used for the exposure, an electron beam can also be used. It is preferable to use extreme ultra-violet light, X-rays, or an electron beam because extremely minute processing can be performed. Note that in the case of performing exposure by scanning of a beam such as an electron beam, a photomask is unnecessary.

For etching of the thin film, a dry etching method, a wet etching method, a sandblast method, or the like can be used.

For the planarization treatment of the thin film, typically, a polishing method such as chemical mechanical polishing (CMP) method or the like can be suitably used. A reflow method in which the conductive layer is fluidized by heat treatment can be suitably used. Alternatively, a combination of the reflow method and the CMP method may be used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and may be set as appropriate depending on the roughness of the surface to be processed.

In order to accurately process the thin film to have a desired thickness, for example, the CMP method is employed. In that case, first, polishing is performed at a constant processing rate until part of the top surface of the thin film is exposed. After that, polishing is performed under a condition with a lower processing rate until the thin film has a desired thickness, so that highly accurate processing can be performed.

Examples of a method for detecting the end of the polishing include an optical method in which the surface of the formation surface is irradiated with light and a change in the reflected light is detected; a physical method in which a change in the polishing resistance received by the processing apparatus from the formation surface is detected; and a method in which a magnetic line is applied to the formation surface and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

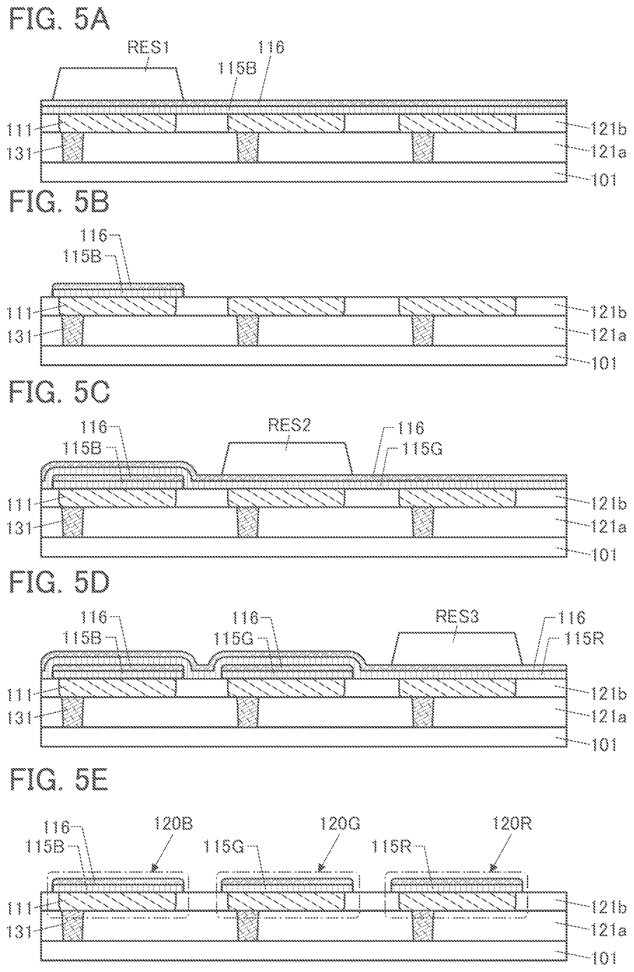

Examples of a method for manufacturing the display device illustrated in FIG. TA will be described with reference to FIG. 5A to FIG. 5E. By the manufacturing method illustrated in FIG. 5A to FIG. 5E, the EL layer 115 and the conductive layer 116 can be processed without using a metal mask.

### [Preparation for Substrate 101]

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, or the like can be given. Alternatively, a single crystal semiconductor substrate using silicon or silicon carbide, a polycrystalline semiconductor substrate, a compound semiconductor substrate of silicon germanium or the like, a semiconductor substrate such as an SOI substrate, or the like can be used.

As the substrate 101, it is particularly preferable to use the semiconductor substrate or the insulating substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

In this embodiment, a substrate including at least a pixel circuit is used as the substrate 101.

### [Formation of Insulating Layer 121a, Plug 131, Insulating Layer 121b, and Conductive Layer 111]

An insulating film to be the insulating layer 121a is formed over the substrate 101. Next, an opening reaching the substrate 101 is formed in the insulating layer 121a in a position where the plug 131 is to be formed. The opening is preferably an opening reaching an electrode or a wiring provided in the substrate 101. Then, a conductive film is formed to fill the opening and planarization treatment is performed to expose atop surface of the insulating layer 121a. In this manner, the plug 131 embedded in the insulating layer 121a can be formed.

The insulating layer 121b is formed over the insulating layer 121a and the plug 131. The insulating layer 121b preferably covers the plug 131. Next, an opening reaching the plug 131 is formed in the insulating layer 121b in a position where the conductive layer 111 is to be formed. Then, a conductive film is formed to fill the opening and planarization treatment is performed to expose a top surface of the insulating layer 121b. Thus, the conductive layer 111 embedded in the insulating layer 121b can be formed. The conductive layer 111 is electrically connected to the plug 131.

The top surface of the insulating layer 121b is preferably substantially aligned with the top surface of the conductive layer 111. The top surface of the conductive layer 111 may be lower than the top surface of the insulating layer 121b, and the conductive layer 111 may be depressed more deeply than the insulating layer 121b.

Alternatively, the level difference between the top surface of the insulating layer 121b and the top surface of the conductive layer 111 is smaller than 0.1 times the thickness of the conductive layer 111, for example.

### [Formation of EL Layer 115 and Conductive Layer 116]

Next, a layer to be the EL layer 115B of the light-emitting element 120B and a layer to be the conductive layer 116 of the light-emitting element 120B are sequentially formed over the conductive layer 111 and the insulating layer 121b. Next, a pattern using a resist RES1 is formed over the conductive layer 116 (FIG. 5A).

The EL layer 115 includes at least a layer containing a light-emitting compound. A structure may be employed in which an electron-injection layer, an electron-transport layer, a charge-generation layer, a hole-transport layer, and a hole-injection layer are stacked in addition to the above. The EL layer 115 can be formed by, for example, a liquid phase method such as an evaporation method or an inkjet method.

The conductive layer 116 is formed to have a transmissive property and a reflective property with respect to visible light. For example, a metal film or an alloy film that is thin enough to transmit visible light can be used. Alternatively, a conductive film having a light-transmitting property (e.g., a metal oxide film) may be stacked over such a film.

Then, after etching is performed using the resist RES1 as a mask to form the conductive layer 116 and the EL layer 115B sequentially, the resist RES1 is removed (FIG. 5B).

Next, a layer to be the EL layer 115G of the light-emitting element 120G and a layer to be the conductive layer 116 of the light-emitting element 120G are sequentially formed over the insulating layer 121b and the conductive layer 111 of the light-emitting element 120B. Next, a pattern using a resist RES2 is formed over the conductive layer 116 (FIG. 5C).

Then, after etching is performed using the resist RES2 as a mask to form the conductive layer 116 and the EL layer 115G sequentially, the resist RES2 is removed.

Next, a layer to be the EL layer 115R of the light-emitting element 120R and a layer to be the conductive layer 116 of the light-emitting element 120R are sequentially formed over the insulating layer 121b, the conductive layer 111 of the light-emitting element 120B, and the conductive layer 111 of the light-emitting element 120G. Next, a pattern using a resist RES3 is formed over the conductive layer 116 (FIG. 5D).

Then, after etching is performed using the resist RES3 as a mask to form the conductive layer 116 and the EL layer 115R sequentially, the resist RES3 is removed (FIG. 5E).

Through the above steps, the display device 100A including the light-emitting element 120R, the light-emitting element 120G, and the light-emitting element 120B can be formed.

### Manufacturing Method Example 2

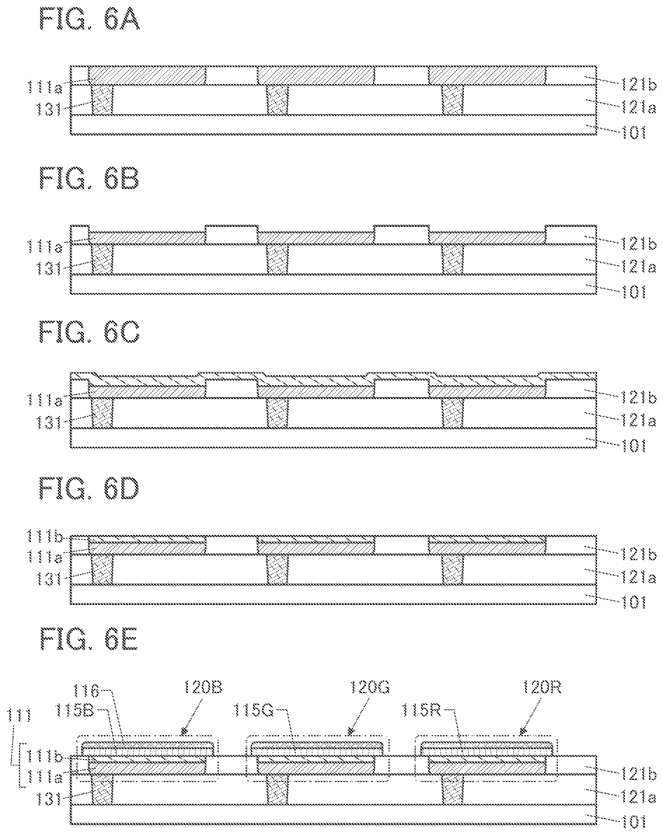

An example of a method for manufacturing the display device 100A illustrated in FIG. 1D will be described with reference to FIG. 6A to FIG. 6E.

First, the plug 131 is formed to be embedded in the insulating layer 121a over the substrate 101, and then the conductive layer 111a is formed to be embedded in the insulating layer 121b over the insulating layer 121a (FIG. 6A).

Then, the conductive layer 111a is removed by etching from the top surface to a desired depth (FIG. 6B). For example, the etching is preferably performed under the condition where the selectivity ratio of the etching rate of the conductive layer 111a to the etching rate of the insulating layer 121b is high to inhibit a reduction of the thickness of the insulating layer 121b.

Next, a conductive film to be the conductive layer 111b is formed over the insulating layer 121b and an opening of the insulating layer 121b over the conductive layer 111a (FIG. 6C).

Next, planarization treatment is performed to expose the top surface of the insulating layer 121b. Thus, the conductive layer 1l1a and the conductive layer 1l1b embedded in the insulating layer 121b can be formed (FIG. 6D).

Here, in the case where aluminum or an alloy containing aluminum is used for the conductive layer 111b, the reflow method and the CMP method are suitably used in combination as the planarization treatment. First, in the reflow method, contact resistance between the conductive layer 111a and the conductive layer 111b can be reduced in some cases to fluidize the conductive layer 111b. In addition, the conductive layer 111b can be favorably embedded in the opening of the insulating layer 121b. Furthermore, unevenness on a surface of the conductive layer 111b can be reduced; thus, the treatment time of the CMP method can be reduced in some cases. Next, the CMP method is performed after the reflow method, and planarization treatment is performed to expose the top surface of the insulating layer 121b.

Next, for example, by the method illustrated in FIG. 5A to FIG. 5E, the EL layer 115B and the conductive layer 116 included in the light-emitting element 120B, the EL layer 115G and the conductive layer 116 included in the light-emitting element 120G, and the EL layer 115R and the conductive layer 116 included in the light-emitting element 120R are formed, whereby the display device 100A illustrated in FIG. 1D is formed (FIG. 6E).

### Manufacturing Method Example 3

An example of a method for manufacturing the display device 100A illustrated in FIG. 3B will be described.

First, in the insulating layer 121b, an opening is formed in a region to be the conductive layer 113. Next, a conductive layer to be the conductive layer 113a is formed in the opening, and the surface of the insulating layer 121b is exposed.

Next, the conductive layer formed in the opening is removed by etching from the top surface to a desired depth.

Next, a conductive film to be the conductive layer 113b is formed over the insulating layer 121b and in the opening of the insulating layer 121b over the conductive layer 113a.

Next, planarization treatment is performed to expose the top surface of the insulating layer 121b. Thus, the conductive layer 113a and the conductive layer 113b embedded in the insulating layer 121b can be formed.

### Structure Example 2

An example of the display device including a transistor will be described below.

### Structure Example 2-1

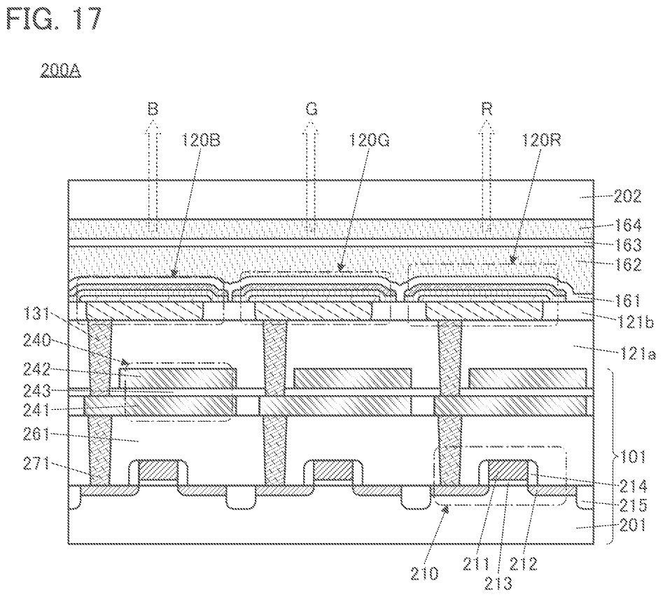

FIG. 17 is a schematic cross-sectional view of a display device 200A.

The display device 200A includes a substrate 201, the light-emitting element 120R, the light-emitting element 120G, the light-emitting element 120B, a capacitor 240, a transistor 210, and the like.

A stacked-layer structure from the substrate 201 to the capacitor 240 corresponds to the above-described substrate 101 in the Structure example 1.

The transistor 210 is a transistor whose channel region is formed in the substrate 201. As the substrate 201, for example, a semiconductor substrate such as a single crystal silicon substrate can be used. The transistor 210 includes part of the substrate 201, a conductive layer 211, a low-resistance region 212, an insulating layer 213, an insulating layer 214, and the like. The conductive layer 211 functions as a gate electrode. The insulating layer 213 is positioned between the substrate 201 and the conductive layer 211 and functions as a gate insulating layer. The low-resistance region 212 is a region where the substrate 201 is doped with an impurity, and functions as one of a source and a drain. The insulating layer 214 is provided to cover side surfaces of the conductive layer 211 and functions as an insulating layer.

In addition, an element isolation layer 215 is provided between two adjacent transistors 210 to be embedded in the substrate 201.

Furthermore, an insulating layer 261 is provided to cover the transistor 210, and the capacitor 240 is provided over the insulating layer 261.

The capacitor 240 includes a conductive layer 241, a conductive layer 242, and an insulating layer 243 positioned therebetween. The conductive layer 241 functions as one electrode of the capacitor 240, the conductive layer 242 functions as the other electrode of the capacitor 240, and the insulating layer 243 functions as a dielectric of the capacitor 240.

The conductive layer 241 is provided over the insulating layer 261 and is electrically connected to one of a source and a drain of the transistor 210 through a plug 271 embedded in the insulating layer 261. The insulating layer 243 is provided to cover the conductive layer 241. The conductive layer 242 is provided in a region overlapping with the conductive layer 241 with the insulating layer 243 therebetween.

The insulating layer 121a is provided to cover the capacitor 240, and the insulating layer 121b, the light-emitting element 120R, the light-emitting element 120G, and the light-emitting element 120B, and the like are provided over the insulating layer 121a. In the example illustrated here, the structure described in FIG. 1A is used as the structures of the light-emitting element 120R, the light-emitting element 120G, the light-emitting element 120B, and the like; however, there is no limitation and a variety of structures described above can be employed.

In the display device 200A, an insulating layer 161, an insulating layer 162, and an insulating layer 163 are provided in this order to cover the conductive layer 116 of the light-emitting element 120. These three insulating layers each function as a protective layer that prevents diffusion of impurities such as water into the light-emitting element 120. As the insulating layer 161 and the insulating layer 163, it is preferable to use an inorganic insulating film with low moisture permeability, such as a silicon oxide film, a silicon nitride film, or an aluminum oxide film. As the insulating layer 162, an organic insulating film having a high light-transmitting property can be used. Using an organic insulating film as the insulating layer 162 can reduce the influence of uneven shape below the insulating layer 162, so that the formation surface of the insulating layer 163 can be a smooth surface. Accordingly, a defect such as a pinhole is unlikely to be generated in the insulating layer 163, leading to higher moisture permeability of the protective layer. Note that the structure of the protective layer covering the light-emitting element 120 is not limited thereto, and a single layer or a two-layer structure may be employed or a stacked-layer structure of four or more layers may be employed.

The display device 200A includes a substrate 202 on the viewing side. The substrate 202 and the substrate 201 are bonded to each other with an adhesive layer 164 having a light-transmitting property. As the substrate 202, a substrate having a light-transmitting property such as a glass substrate, a quartz substrate, a sapphire substrate, or a plastic substrate can be used.

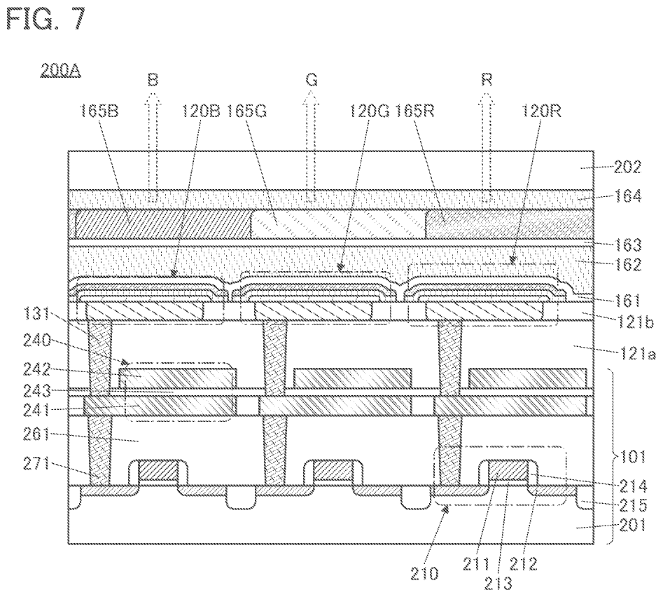

As illustrated in FIG. 7, a coloring layer 165R overlapping with the light-emitting element 120R, a coloring layer 165G overlapping with the light-emitting element 120G, and a coloring layer 165B overlapping with the light-emitting element 120B may be provided over the insulating layer 163. For example, the coloring layer 165R transmits red light, the coloring layer 165G transmits green light, and the coloring layer 165B transmits blue light. This can increase the color purity of light from the light-emitting elements, so that a display device with higher display quality can be achieved. Furthermore, the positional alignment of the light-emitting units and the coloring layers is easier in the case where the coloring layers are formed over the insulating layer 163 than in the after-mentioned case where the coloring layers are formed over the substrate 202.

The structure illustrated in FIG. 17 and FIG. 7 can achieve a display device with extremely high resolution and high display quality.

### Structure Example 2-2

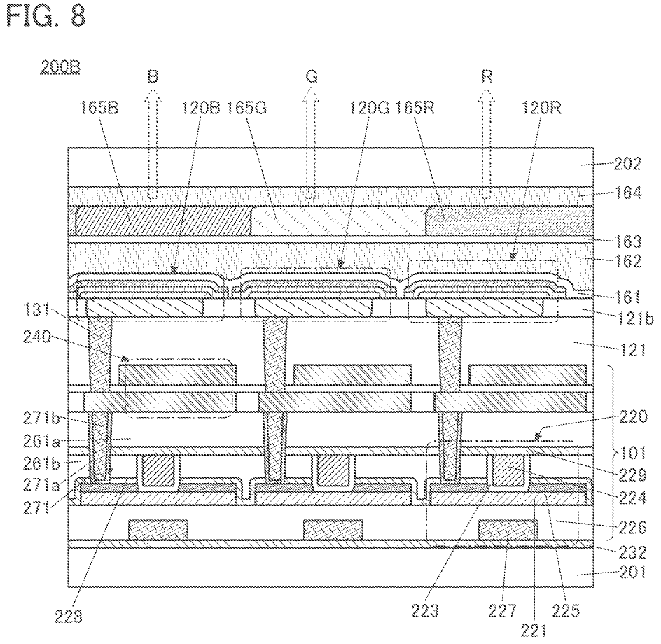

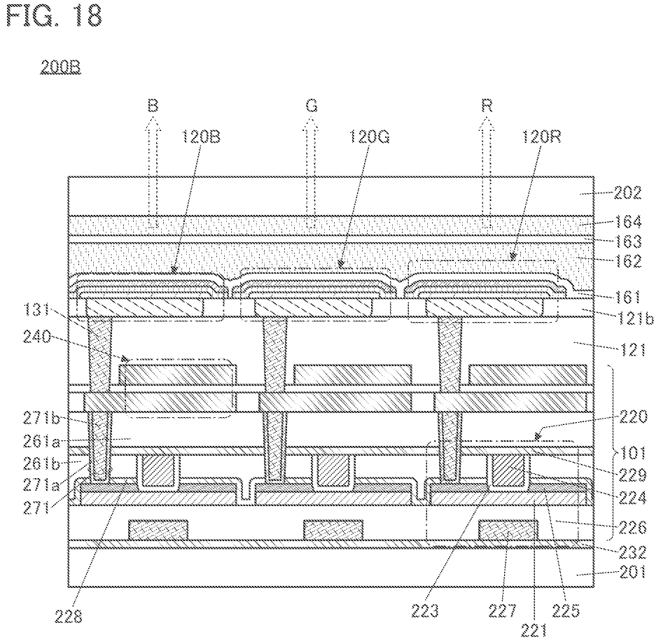

FIG. 18 is a schematic cross-sectional view of a display device 200B. The display device 200B is different from the above-described display device 200A illustrated in FIG. 17 mainly in that a structure of a transistor. FIG. 8 is different from FIG. 18 mainly in that the coloring layer 165R, the coloring layer 165G, and the coloring layer 165B are included.

A transistor 220 is a transistor in which a metal oxide (also referred to as an oxide semiconductor) is used in a semiconductor layer where a channel is formed.

The transistor 220 includes a semiconductor layer 221, an insulating layer 223, a conductive layer 224, a pair of conductive layers 225, an insulating layer 226, a conductive layer 227, and the like.

As the substrate 201 over which the transistor 220 is provided, the above-described insulating substrate or semiconductor substrate can be used.

An insulating layer 232 is provided over the substrate 201. The insulating layer 232 functions as a barrier layer that prevents diffusion of impurities such as water or hydrogen from the substrate 201 into the transistor 220 and release of oxygen from the semiconductor layer 221 to the insulating layer 232 side. As the insulating layer 232, it is preferable to use, for example, a film in which hydrogen or oxygen is less likely to be diffused than in a silicon oxide film such as an aluminum oxide film, a hafnium oxide film, or a silicon nitride film.

The conductive layer 227 is provided over the insulating layer 232, and the insulating layer 226 is provided to cover the conductive layer 227. The conductive layer 227 functions as a first gate electrode of the transistor 220, and part of the insulating layer 226 functions as a first gate insulating layer. For the insulating layer 226 at least in a portion in contact with the semiconductor layer 221, an oxide insulating film such as a silicon oxide film is preferably used.

A top surface of the insulating layer 226 is preferably planarized.

The semiconductor layer 221 is provided over the insulating layer 226. The semiconductor layer 221 preferably includes a film of a metal oxide exhibiting semiconductor characteristics (also referred to as an oxide semiconductor). The material that can be suitably used for the semiconductor layer 221 is described in detail later.

The pair of conductive layers 225 is provided over and in contact with the semiconductor layer 221, and functions as a source electrode and a drain electrode.

An insulating layer 228 is provided to cover top surfaces and side surfaces of the pair of conductive layers 225, side surfaces of the semiconductor layer 221, and the like, and an insulating layer 261b is provided over the insulating layer 228. The insulating layer 228 functions as a barrier layer that prevents diffusion of impurities such as water or hydrogen from the insulating layer 261b or the like to the semiconductor layer 221 and release of oxygen from the semiconductor layer 221. As the insulating layer 228, an insulating film similar to the insulating layer 232 can be used.

An opening reaching the semiconductor layer 221 is provided in the insulating layer 228 and the insulating layer 261b. The insulating layer 223 that is in contact with the side surfaces of the insulating layer 261b, the insulating layer 228, and the conductive layer 225, and a top surface of the semiconductor layer 221, and the conductive layer 224 are embedded inside the opening. The conductive layer 224 functions as a second gate electrode and the insulating layer 223 functions as a second gate insulating layer.

A top surface of the conductive layer 224, a top surface of the insulating layer 223, and a top surface of the insulating layer 261b are planarized so that they are substantially level with each other, and an insulating layer 229 and an insulating layer 261a are provided to cover these layers.

The insulating layer 261a and the insulating layer 261b function as an interlayer insulating layer. The insulating layer 229 functions as a barrier layer that prevents diffusion of impurities such as water or hydrogen from the insulating layer 261a or the like to the transistor 220. As the insulating layer 229, the insulating layer 228 and an insulating film similar to the insulating layer 232 can be used.

The plug 271 electrically connected to one of the pair of conductive layers 225 is provided to be embedded in the insulating layer 261a, the insulating layer 229, and the insulating layer 261b. Here, the plug 271 preferably includes a conductive layer 271b in contact with atop surface of the conductive layer 271a and a conductive layer 271a covering side surfaces of openings of the insulating layer 261a, the insulating layer 261b, the insulating layer 229, and the insulating layer 228, and part of a top surface of the conductive layer 225. In this case, a conductive material in which hydrogen and oxygen are unlikely to be diffused is preferably used for the conductive layer 271a.

### Structure Example 2-3

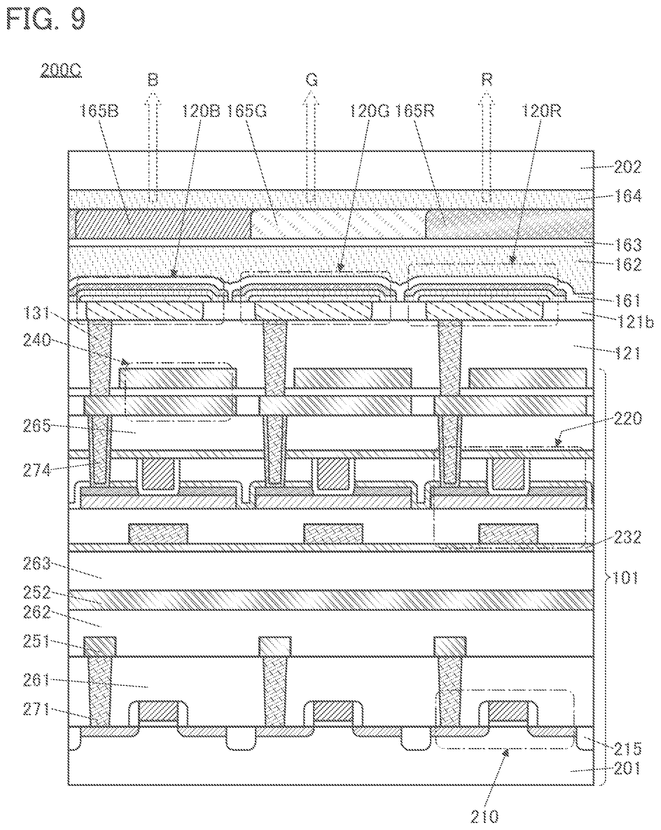

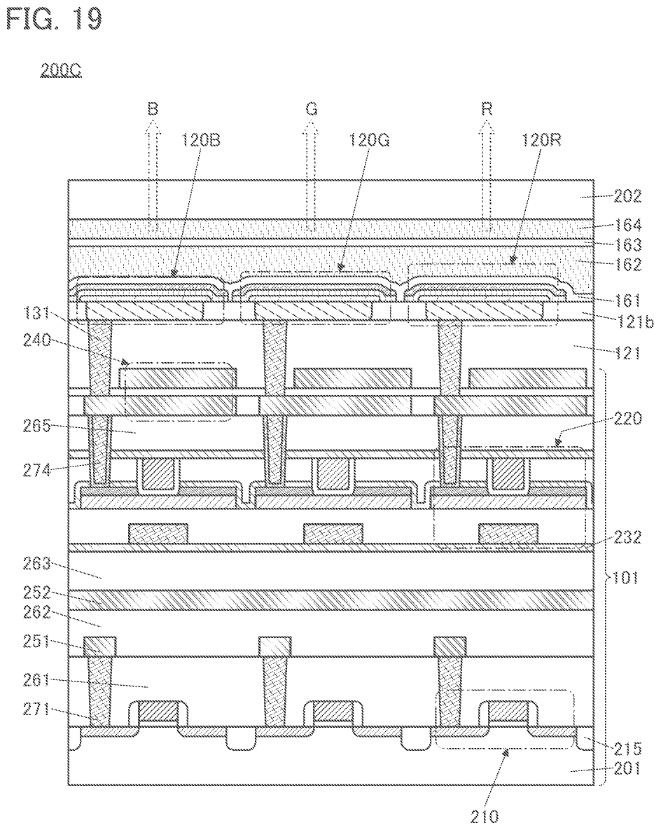

FIG. 19 is a schematic cross-sectional view of a display device 200C. The display device 200C has a structure in which the transistor 210 whose channel is formed in the substrate 201 and the transistor 220 including a metal oxide in the semiconductor layer where the channel is formed are stacked. FIG. 9 is different from FIG. 19 mainly in that the coloring layer 165R, the coloring layer 165G, and the coloring layer 165B are included.

The insulating layer 261 is provided to cover the transistor 210 and a conductive layer 251 is provided over the insulating layer 261. In addition, an insulating layer 262 is provided to cover the conductive layer 251 and a conductive layer 252 is provided over the insulating layer 262. The conductive layer 251 and the conductive layer 252 each function as a wiring. An insulating layer 263 and the insulating layer 232 are provided to cover the conductive layer 252, and the transistor 220 is provided over the insulating layer 232. An insulating layer 265 is provided to cover the transistor 220, and the capacitor 240 is provided over the insulating layer 265. The capacitor 240 and the transistor 220 are electrically connected to each other through a plug 274.

The transistor 220 can be used as a transistor included in a pixel circuit. The transistor 210 can also be used as a transistor included in a pixel circuit or a transistor included in a driver circuit (a gate line driver circuit or a source line driver circuit) for driving the pixel circuit. The transistor 210 and the transistor 220 can also be used as transistors included in a variety of circuits such as an arithmetic circuit and a memory circuit.

With such a structure, not only the pixel circuit but also the driver circuit or the like can be formed directly under the light-emitting unit; thus, the display device can be downsized as compared with the case where the driver circuit is provided around a display region.

### Structure Example 2-4

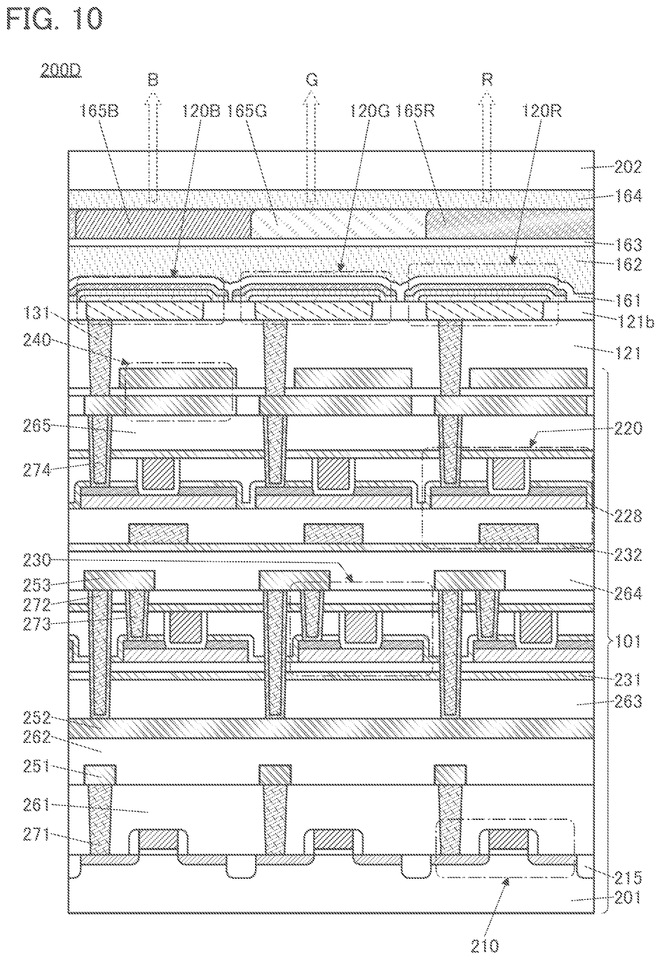

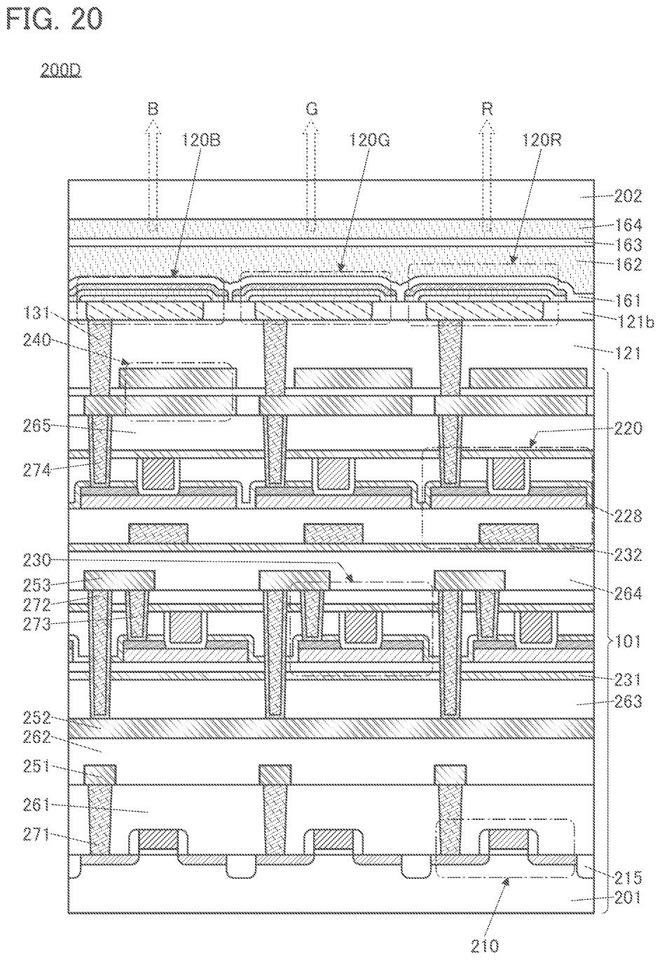

FIG. 20 is a schematic cross-sectional view of a display device 200D. The display device 200D is different from the above-described display device 200C illustrated in FIG. 19 mainly in that two transistors using an oxide semiconductor are stacked. FIG. 10 is different from FIG. 20 mainly in that the coloring layer 165R, the coloring layer 165G, and the coloring layer 165B are included.

The display device 200D includes a transistor 230 between the transistor 210 and the transistor 220. The transistor 230 has a structure similar to that of the transistor 220 except that the first gate electrode is not included. Note that the transistor 230 may have a structure including the first gate electrode.

The insulating layer 263 and an insulating layer 231 are provided to cover the conductive layer 252, and the transistor 230 is provided over the insulating layer 231. The transistor 230 and the conductive layer 252 are electrically connected to each other through a plug 273, a conductive layer 253, and a plug 272. An insulating layer 264 and the insulating layer 232 are provided to cover the conductive layer 253, and the transistor 220 is provided over the insulating layer 232.

The transistor 220 functions as, for example, a transistor for controlling current flowing through the light-emitting element 120. The transistor 230 functions as a selection transistor for controlling the selection state of a pixel. The transistor 210 functions as a transistor included in a driver circuit for driving the pixel, for example.

When three or more layers in which a transistor is formed are stacked in this manner, the area occupied by the pixel can be further reduced and a high-resolution display device can be achieved.

Components such as a transistor that can be used in the display device will be described below.

### [Transistor]

The transistors each include a conductive layer functioning as a gate electrode, a semiconductor layer, a conductive layer functioning as a source electrode, a conductive layer functioning as a drain electrode, and an insulating layer functioning as a gate insulating layer.

Note that there is no particular limitation on the structure of the transistor included in the display device of one embodiment of the present invention. For example, a planar transistor, a staggered transistor, or an inverted staggered transistor may be used. A top-gate or a bottom-gate transistor structure may be employed. Gate electrodes may be provided above and below a channel.

There is no particular limitation on the crystallinity of a semiconductor material used for the transistor, and an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used because deterioration of the transistor characteristics can be inhibited.

In particular, a transistor that uses a metal oxide film for a semiconductor layer where a channel is formed will be described below.

As a semiconductor material used for the transistors, a metal oxide whose energy gap is greater than or equal to 2 eV, preferably greater than or equal to 2.5 eV, further preferably greater than or equal to 3 eV can be used. A typical example thereof is a metal oxide containing indium, and for example, a CAC-OS described later or the like can be used.

A transistor using a metal oxide having a wider band gap and a lower carrier density than silicon has a low off-state current; thus, charges accumulated in a capacitor that is connected in series with the transistor can be held for a long time.

The semiconductor layer can be, for example, a film represented by an In-M-Zn-based oxide that contains indium, zinc, and M (M is a metal such as aluminum, titanium, gallium, germanium, yttrium, zirconium, lanthanum, cerium, tin, neodymium, or hafnium).

In the case where the metal oxide contained in the semiconductor layer is an In-M-Zn-based oxide, it is preferable that the atomic ratio of metal elements of a sputtering target used for forming a film of the In-M-Zn oxide satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, or In:M:Zn=5:1:8. Note that the atomic ratio in the formed semiconductor layer varies from the above atomic ratio of metal elements of the sputtering target in a range of ±40%.

A metal oxide film with low carrier density is used as the semiconductor layer. For example, for the semiconductor layer, a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such a metal oxide is referred to as a highly purified intrinsic or substantially highly purified intrinsic metal oxide. The metal oxide has a low density of defect states and can be regarded as a metal oxide having stable characteristics.

Note that the composition is not limited to those, and an oxide semiconductor having an appropriate composition may be used depending on required semiconductor characteristics and electrical characteristics (field-effect mobility, threshold voltage, or the like) of the transistor. In addition, to obtain the required semiconductor characteristics of the transistor, it is preferable that the carrier density, impurity concentration, defect density, atomic ratio between a metal element and oxygen, interatomic distance, density, and the like of the semiconductor layer be set to be appropriate.

When silicon or carbon, which is one of Group 14 elements, is contained in the metal oxide that constitutes the semiconductor layer, oxygen vacancies are increased in the semiconductor layer, and the semiconductor layer becomes n-type. Thus, the concentration (concentration obtained by secondary ion mass spectrometry) of silicon or carbon in the semiconductor layer is set lower than or equal to 2×10¹⁸ atoms/cm³, preferably lower than or equal to 2×10¹⁷ atoms/cm³.

Alkali metal and alkaline earth metal might generate carriers when bonded to a metal oxide, in which case the off-state current of the transistor might be increased. Thus, the concentration of alkali metal or alkaline earth metal in the semiconductor layer that is obtained by secondary ion mass spectrometry is set to lower than or equal to 1×10¹⁸ atoms/cm³, preferably lower than or equal to 2×10¹⁶ atoms/cm³.

When nitrogen is contained in the metal oxide that constitutes the semiconductor layer, electrons serving as carriers are generated and the carrier density increases, so that the semiconductor layer easily becomes n-type. As a result, a transistor including a metal oxide that contains nitrogen is likely to be normally on. Hence, the concentration of nitrogen, which is obtained by secondary ion mass spectrometry, in the semiconductor layer is preferably set to lower than or equal to 5×10¹⁸ atoms/cm³.

Oxide semiconductors are classified into a single crystal oxide semiconductor and a non-single-crystal oxide semiconductor. Examples of the non-single-crystal oxide semiconductor include a CAAC-OS (c-axis-aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

In addition, a CAC-OS (cloud-aligned composite oxide semiconductor) may be used for a semiconductor layer of a transistor disclosed in one embodiment of the present invention.

Note that the non-single-crystal oxide semiconductor can be suitably used for a semiconductor layer of a transistor disclosed in one embodiment of the present invention. As the non-single-crystal oxide semiconductor, the nc-OS or the CAAC-OS can be suitably used.

In one embodiment of the present invention, a CAC-OS is preferably used for a semiconductor layer of a transistor. The use of the CAC-OS allows the transistor to have high electrical characteristics or high reliability.

The semiconductor layer may be a mixed film including two or more of a region of a CAAC-OS, a region of a polycrystalline oxide semiconductor, a region of an nc-OS, a region of an a-like OS, and a region of an amorphous oxide semiconductor. The mixed film has, for example, a single-layer structure or a stacked-layer structure including two or more of the above regions in some cases.

### <Composition of CAC-OS>

The composition of a CAC-OS that can be used in a transistor disclosed in one embodiment of the present invention is described below.

The CAC-OS is, for example, a composition of a material in which elements that constitute a metal oxide are unevenly distributed to have a size of greater than or equal to 0.5 nm and less than or equal to 10 nm, preferably greater than or equal to 1 nm and less than or equal to 2 nm, or a similar size. Note that in the following description, a state in which one or more metal elements are unevenly distributed and regions including the metal element(s) are mixed to have a size of greater than or equal to 0.5 nm and less than or equal to 10 nm, preferably greater than or equal to 1 nm and less than or equal to 2 nm, or a similar size in a metal oxide is referred to as a mosaic pattern or a patch-like pattern.

Note that the metal oxide preferably contains at least indium. In particular, indium and zinc are preferably contained. In addition to these, one or a plurality of kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For instance, a CAC-OS in an In-Ga—Zn oxide (an In-Ga—Zn oxide in the CAC-OS may be particularly referred to as CAC-IGZO) has a composition in which materials are separated into indium oxide (hereinafter, InO_{X1} (X1 is a real number greater than 0)) or indium zinc oxide (hereinafter, In_{X2}Zn_{Y2}O_{Z2} (X2, Y2, and Z2 are real numbers greater than 0)) and gallium oxide (hereinafter, GaO_{X3} (X3 is a real number greater than 0)) or gallium zinc oxide (hereinafter, Ga_{X4}Zn_{Y4}O_{Z4} (X4, Y4, and Z4 are real numbers greater than 0)), for example, so that a mosaic pattern is formed, and mosaic-like InO_{X1} or In_{X2}Zn_{Y2}O_{Z2} is evenly distributed in the film (which is hereinafter also referred to as cloud-like).

That is, the CAC-OS is a composite metal oxide having a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is larger than the atomic ratio of In to the element M in a second region, the first region is regarded as having a higher In concentration than the second region.

Note that IGZO is a common name and sometimes refers to one compound formed of In, Ga, Zn, and O. A typical example is a crystalline compound represented by InGaO₃(ZnO)ₘ₁ (m1 is a positive integer) or In(₁₊ₓ₀)Ga(₁₋ₓ₀)O₃(ZnO)ₘ₀ (−1≤x0≤1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane direction without alignment.

On the other hand, the CAC-OS relates to the material composition of a metal oxide. In the material composition of a CAC-OS containing In, Ga, Zn, and O, some regions that contain Ga as a main component and are observed as nanoparticles and some regions that contain In as a main component and are observed as nanoparticles are randomly dispersed in a mosaic pattern. Therefore, the crystal structure is a secondary element for the CAC-OS.

Note that in the CAC-OS, a stacked-layer structure including two or more films with different compositions is not included. For example, a two-layer structure of a film containing In as a main component and a film containing Ga as a main component is not included.

A boundary between the region including GaO_{X3} as a main component and the region including In_{X2}Zn_{Y2}O_{Z2} or InO_{X1} as a main component is not clearly observed in some cases.

Note that in the case where one kind or a plurality of kinds selected from aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium, the CAC-OS refers to a composition in which some regions that contain the metal element(s) as a main component and are observed as nanoparticles and some regions that contain In as a main component and are observed as nanoparticles are each randomly dispersed in a mosaic pattern.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. Furthermore, the ratio of the flow rate of an oxygen gas to the total flow rate of the deposition gas at the time of deposition is preferably as low as possible, and for example, the ratio of the flow rate of the oxygen gas is preferably higher than or equal to 0% and lower than 30%, further preferably higher than or equal to 0% and lower than or equal to 10%.

The CAC-OS is characterized in that a clear peak is not observed when measurement is conducted using a θ/2θ scan by an Out-of-plane method, which is an X-ray diffraction (XRD) measurement method. That is, it is found from the X-ray diffraction measurement that no alignment in the a-b plane direction and the c-axis direction is observed in the measured region.

In an electron diffraction pattern of the CAC-OS which is obtained by irradiation with an electron beam with a probe diameter of 1 nm (also referred to as a nanometer-sized electron beam), a ring-like region with high luminance and a plurality of bright spots in the ring-like region are observed. Thus, the electron diffraction pattern indicates that the crystal structure of the CAC-OS includes an nc (nano-crystal) structure with no alignment in a plan-view direction and a cross-sectional direction.

Moreover, for example, it can be confirmed by EDX mapping obtained using energy dispersive X-ray spectroscopy (EDX) that the CAC-OS in the In-Ga—Zn oxide has a composition in which the region including GaO_{X3} as a main component and the region including In_{X2}Zn_{Y2}O_{Z2} or InO_{X1} as a main component are unevenly distributed and mixed.

The CAC-OS has a structure different from that of an IGZO compound in which metal elements are evenly distributed, and has characteristics different from those of the IGZO compound. That is, in the CAC-OS, a region including GaO_{X3} or the like as a main component and the region including In_{X2}Zn_{Y2}O_{Z2} or InO_{X1} as a main component are separated to form a mosaic pattern.

The conductivity of the region including In_{X2}Zn_{Y2}O_{Z2} or InO_{X1} as a main component is higher than that of the region including GaO_{X3} or the like as a main component. In other words, when carriers flow through the region including In_{X2}Zn_{Y2}O_{Z2} or InO_{X1} as a main component, the conductivity of a metal oxide is exhibited. Accordingly, when the region including In_{X2}Zn_{Y2}O_{Z2} or InO_{X1} as a main component are distributed in a metal oxide like a cloud, high field-effect mobility (μ) can be achieved.

In contrast, the insulating property of the region including GaO_{X3} or the like as a main component is higher than that of the region including In_{X2}Zn_{Y2}O_{Z2} or InO_{X1} as a main component. In other words, when the region including GaO_{X3} or the like as a main component are distributed in a metal oxide, leakage current can be inhibited and favorable switching operation can be achieved.

Accordingly, when the CAC-OS is used for a semiconductor element, the insulating property derived from GaO_{X3} or the like and the conductivity derived from In_{X2}Zn_{Y2}O_{Z2} or InO_{X1} complement each other, whereby a high on-state current (Iₒₙ) and high field-effect mobility (μ) can be achieved.

A semiconductor element using a CAC-OS has high reliability. Thus, the CAC-OS is suitably used in a variety of semiconductor devices typified by a display.

Since a transistor including the CAC-OS in a semiconductor layer has high field-effect mobility and high drive capability, the use of the transistor in a driver circuit, a typical example of which is a scan line driver circuit that generates a gate signal, can provide a display device with a narrow bezel width (also referred to a narrow bezel). Furthermore, with the use of the transistor in a signal line driver circuit that is included in a display device (particularly in a demultiplexer connected to an output terminal of a shift register included in a signal line driver circuit), a display device to which a small number of wirings are connected can be provided.

Furthermore, unlike a transistor including low-temperature polysilicon, the transistor including a CAC-OS in the semiconductor layer does not need a laser crystallization step. Thus, the manufacturing cost of a display device can be reduced, even when the display device is formed using a large substrate. In addition, the transistor including a CAC-OS in the semiconductor layer is preferably used for a driver circuit and a display portion in a large display device having high resolution such as ultra-high definition (“4K resolution”, “4K2K”, and “4K”) or super high definition (“8K resolution”, “8K4K”, and “8K”), in which case writing can be performed in a short time and display defects can be reduced.

Alternatively, silicon may be used for a semiconductor in which a channel of a transistor is formed. As the silicon, amorphous silicon may be used but silicon having crystallinity is particularly preferably used. For example, microcrystalline silicon, polycrystalline silicon, or single-crystal silicon are preferably used. In particular, polycrystalline silicon can be formed at a temperature lower than that for single crystal silicon and has higher field-effect mobility and higher reliability than amorphous silicon.

### [Conductive Layer]

As materials for a conductive layer such as a wiring or an electrode that forms a display device in addition to a gate, a source, and a drain of a transistor, metals such as aluminum, titanium, chromium, nickel, copper, yttrium, zirconium, molybdenum, silver, tantalum, and tungsten, or an alloy containing any of these metals as its main component can be given. A single-layer structure or stacked-layer structure including a film containing any of these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Copper containing manganese is preferably used because it increases controllability of a shape by etching.

### [Insulating Layer]

Examples of an insulating material that can be used for the insulating layers include a resin such as an acrylic resin or an epoxy resin, a resin having a siloxane bond, such as silicone, and an inorganic insulating material such as silicon oxide, silicon oxynitride, silicon nitride oxide, silicon nitride, or aluminum oxide.

Note that in this specification, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The light-emitting element is preferably provided between a pair of insulating films with low water permeability. In that case, impurities such as water can be inhibited from entering the light-emitting element, and thus a decrease in device reliability can be inhibited.

Examples of the insulating film with low water permeability include a film containing nitrogen and silicon, such as a silicon nitride film and a silicon nitride oxide film, and a film containing nitrogen and aluminum, such as an aluminum nitride film. Alternatively, a silicon oxide film, a silicon oxynitride film, an aluminum oxide film, or the like may be used.

For example, the moisture vapor transmission rate of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

### Structure Example of Display Module

A structure example of a display module including the display device of one embodiment of the present invention will be described below.

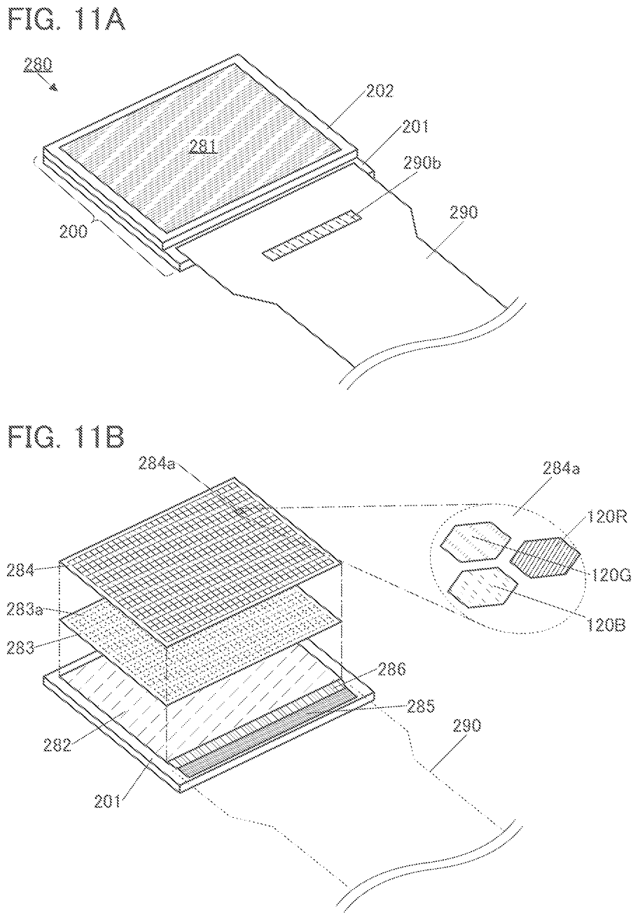

FIG. 11A is a schematic perspective view of a display module 280. The display module 280 includes the display device 200 and an FPC 290. Any of the display devices (the display device 200A to the display device 200D) described in Structure example 2 can be used as the display device 200.

The display module 280 includes the substrate 201 and the substrate 202. A display portion 281 is also included on the substrate 202 side. The display portion 281 is a region of the display module 280 where an image is displayed and is a region where light emitted from pixels provided in a pixel portion 284 described later can be seen. The display module 280 may include a source driver IC 290b.

FIG. 11B illustrates a perspective view schematically illustrating a structure on the substrate 201 side. The substrate 201 has a structure in which a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 201. The terminal portion 285 and the circuit portion 282 are electrically connected to each other through a wiring portion 286 formed of a plurality of wirings.

The pixel portion 284 includes a plurality of pixels 284a that are periodically arranged. An enlarged view of one pixel 284a is illustrated on the right side of FIG. 11B. The pixel 284a includes the light-emitting element 120R, the light-emitting element 120G, and the light-emitting element 120B.

The pixel circuit portion 283 includes a plurality of pixel circuits 283a that are periodically arranged. The plurality of pixel circuits 283a may be arranged in a delta pattern illustrated in FIG. 11B. With the delta pattern that enables high-density arrangement of pixel circuits, a high-resolution display device can be provided.

One pixel circuit 283a is a circuit that controls light emission of three light-emitting elements included in one pixel 284a. One pixel circuit 283a may be provided with three circuits for controlling light emission of respective light-emitting elements. For example, the pixel circuit 283a for one light-emitting element can include at least one selection transistor, one current control transistor (driving transistor), and a capacitor. In this case, agate signal is input to agate of the selection transistor and a source signal is input to one of a source and a drain thereof. With such a structure, an active-matrix display device is achieved.

The circuit portion 282 includes a circuit for driving the pixel circuits 283a in the pixel circuit portion 283. For example, a gate line driver circuit and a source line driver circuit are preferably included. In addition, an arithmetic circuit, a memory circuit, a power supply circuit, or the like may be included.

The FPC 290 functions as a wiring for supplying a video signal or a power supply potential to the circuit portion 282 from the outside. In addition, an IC may be mounted on the FPC 290.

The display module 280 can have a structure in which the pixel circuit portion 283, the circuit portion 282, and the like are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, and further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a device for VR such as ahead-mounted display or a glasses-type device for AR. For example, even in the case of a structure in which the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without limitation to the above, the display module 280 can also be suitably used for an electronic device having a relatively small display portion. For example, the display module 280 can also be suitably used for a display portion of a wearable electronic device such as a wrist watch.

At least part of this embodiment can be implemented in combination with the other embodiments described in this specification as appropriate.

### Embodiment 2

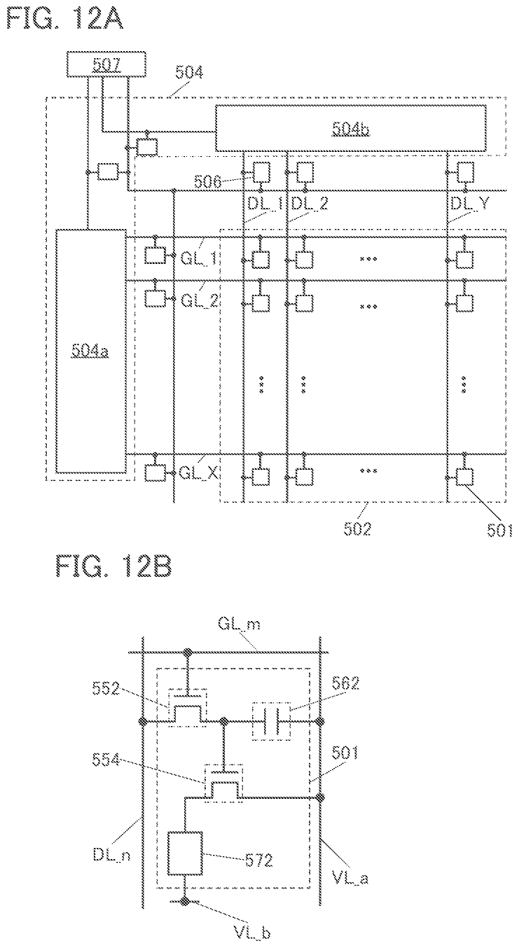

In this embodiment, a display device of one embodiment of the present invention will be described with reference to FIG. 12.

A display device illustrated in FIG. 12A includes a pixel portion 502, a driver circuit portion 504, protection circuits 506, and a terminal portion 507. Note that in the display device of one embodiment of the present invention, a structure in which the protection circuits 506 are not provided may be employed.

The pixel portion 502 includes a plurality of pixel circuits 501 arranged in X rows and Y columns (X and Y each independently represent a positive integer of 2 or more). Each of the pixel circuits 501 includes a circuit for driving a display element.

The driver circuit portion 504 includes driver circuits such as a gate driver 504a that outputs a scanning signal to gate lines GL_1 to GL_X and a source driver 504b that supplies a data signal to data lines DL_1 to DL_Y. The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is supplied to a wiring to which the protection circuit 506 is connected, establishes continuity between the wiring and another wiring. The protection circuit 506 illustrated in FIG. 12A is connected to a variety of wirings such as the gate lines GL that are wirings between the gate driver 504a and the pixel circuits 501 and the data lines DL that are wirings between the source driver 504b and the pixel circuits 501, for example.

The gate driver 504a and the source driver 504b may be provided over the same substrate as the pixel portion 502, or a substrate where a gate driver circuit or a source driver circuit is separately formed (e.g., a driver circuit board formed using a single crystal semiconductor or a polycrystalline semiconductor) may be mounted on the substrate by COG or TAB (Tape Automated Bonding).

In particular, the gate driver 504a and the source driver 504b are preferably placed below the pixel portion 502.

The plurality of pixel circuits 501 illustrated in FIG. 12A can have a configuration illustrated in FIG. 12B, for example.

The pixel circuit 501 illustrated in FIG. 12B includes transistors 552 and 554, a capacitor 562, and a light-emitting element 572. A data line DL_n, a gate line GL_m, a potential supply line VL_a, a power supply line VL_b, and the like are connected to the pixel circuit 501.

Note that a high power supply potential VDD is supplied to one of the potential supply line VL_a and the potential supply line VL_b, and a low power supply potential VSS is supplied to the other. Current flowing through the light-emitting element 572 is controlled in accordance with a potential supplied to a gate of the transistor 554, whereby the luminance of light emitted from the light-emitting element 572 is controlled.

At least part of this embodiment can be implemented in combination with the other embodiments described in this specification as appropriate.

### Embodiment 3

A pixel circuit including a memory for correcting gray levels displayed by pixels that can be used in the display device of one embodiment of the present invention and a display device including the pixel circuit will be described below.

### [Circuit Configuration]

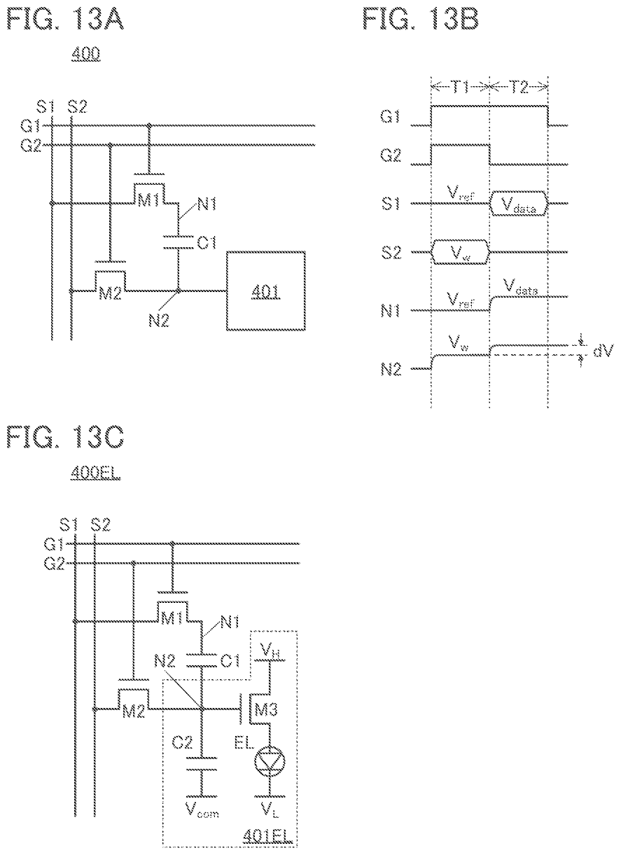

FIG. 13A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic EL element or an LED element can be used. In addition, a liquid crystal element, a MEMS (Micro Electro Mechanical Systems) element, or the like can also be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 1, can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### [Driving Method Example]

Next, an example of a method for operating the pixel circuit 400 is described with reference to FIG. 13B. FIG. 13B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 13B, one frame period is divided into a period T1 and a period T2. The period T1 is a period in which a potential is written to the node N2, and the period T2 is a period in which a potential is written to the node N1.

### [Period T1]

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}−V_{ref} is retained in the capacitor C1.

### [Period T2]

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential Vw and the potential dV is input to the circuit 401. Note that although the potential dV is shown as a positive value in FIG. 13B, the potential dV may be a negative value. That is, the second data potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential V_{data}.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case of using a light-emitting element, high-dynamic range (HDR) display or the like can be performed. In the case of using a liquid crystal element, overdriving or the like can be achieved.

### Application Example

A pixel circuit 400EL illustrated in FIG. 13C includes a circuit 401EL. The circuit 401EL includes a light-emitting element EL, a transistor M3, and a capacitor C2.

In the transistor M3, a gate is connected to the node N2 and one electrode of the capacitor C2, one of a source and a drain is connected to a wiring that supplies a potential VH, and the other is connected to one electrode of the light-emitting element EL. The other electrode of the capacitor C2 is connected to a wiring that supplies a potential V_{com}. The other electrode of the light-emitting element EL is connected to a wiring that supplies a potential V_{L}.

The transistor M3 has a function of controlling a current to be supplied to the light-emitting element EL. The capacitor C2 functions as a storage capacitor. The capacitor C2 can be omitted when not needed.

Note that although the structure in which the anode side of the light-emitting element EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting element EL when a high potential is supplied to the gate of the transistor M3, which enables HDR display, for example. Moreover, a variation in the electrical characteristics of the transistor M3 and the light-emitting element EL can be corrected by supply of a correction signal to the wiring S1 or the wiring S2.

Note that the configuration is not limited to the circuits illustrated in FIG. 13C, and a configuration to which a transistor, a capacitor, or the like is further added may be employed.

At least part of this embodiment can be implemented in combination with the other embodiments described in this specification as appropriate.

### Embodiment 4

In this embodiment, structure examples of an electronic device for which the display device of one embodiment of the present invention is used will be described.

The display device and the display module of one embodiment of the present invention can be applied to a display portion of an electronic device or the like having a display function. Examples of such an electronic device include a digital camera, a digital video camera, a digital photo frame, a mobile phone, a portable game machine, a portable information terminal, and an audio reproducing device, in addition to electronic devices with a relatively large screen, such as a television device, a laptop personal computer, a monitor device, digital signage, a pachinko machine, and a game machine.

In particular, the display device and the display module of one embodiment of the present invention can have a high resolution, and thus can be favorably used for an electronic device having a relatively small display portion. As these electronic devices, for example, a watch-type or bracelet-type information terminal device (wearable device), and wearable devices worn on a head, such as a device for VR such as a head mounted display and a glasses-type device for AR can be given.

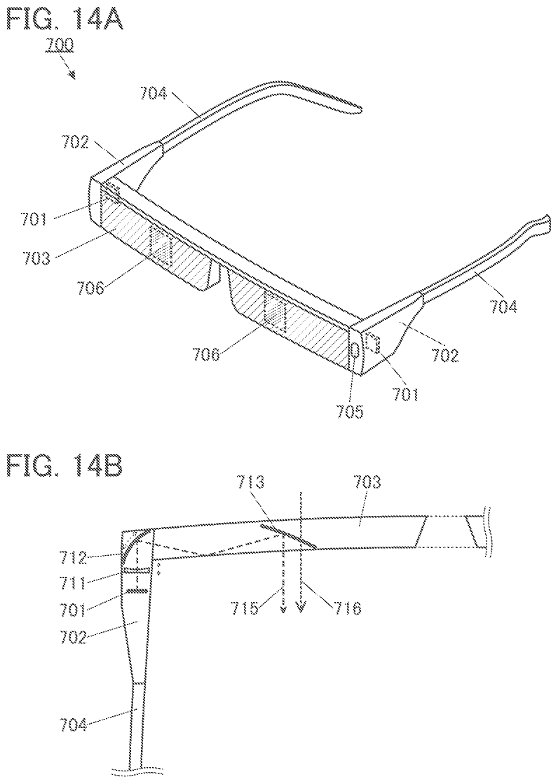

FIG. 14A is a perspective view of an electronic device 700 that is of a glasses type. The electronic device 700 includes a pair of display panels 701, a pair of housings 702, a pair of optical members 703, a pair of temples 704, and the like.

The electronic device 700 can project an image displayed on the display panel 701 onto a display region 706 of the optical member 703. Since the optical members 703 have a light-transmitting property, a user can see images displayed on the display regions 706, which are superimposed on transmission images seen through the optical members 703. Thus, the electronic device 700 is an electronic device capable of AR display.

One housing 702 is provided with a camera 705 capable of capturing images of the front side. Although not illustrated, one of the housings 702 is provided with a wireless receiver or a connector to which a cable can be connected, whereby a video signal or the like can be supplied to the housing 702. Furthermore, when the housing 702 is provided with an acceleration sensor such as a gyroscope sensor, the orientation of the user's head can be detected and an image corresponding to the orientation can be displayed on the display region 706. Moreover, the housing 702 is preferably provided with a battery, in which case charging can be performed with or without a wire.

Next, a method for projecting an image on the display region 706 of the electronic device 700 is described with reference to FIG. 14B. The display panel 701, a lens 711, and a reflective plate 712 are provided in the housing 702. A reflective surface 713 functioning as a half mirror is provided in a portion corresponding to the display region 706 of the optical member 703.

Light 715 emitted from the display panel 701 passes through the lens 711 and is reflected by the reflective plate 712 to the optical member 703 side. In the optical member 703, the light 715 is fully reflected repeatedly by end surfaces of the optical member 703 and reaches the reflective surface 713, whereby an image is projected on the reflective surface 713. Accordingly, the user can see both the light 715 reflected by the reflective surface 713 and transmitted light 716 transmitted through the optical member 703 (including the reflective surface 713).

FIG. 14 shows an example in which the reflective plate 712 and the reflective surface 713 each have a curved surface. This can increase optical design flexibility and reduce the thickness of the optical member 703, compared to the case where they have flat surfaces. Note that the reflective plate 712 and the reflective surface 713 may be flat.

The reflective plate 712 can use a component having a mirror surface, and preferably has high reflectance. As the reflective surface 713, a half mirror utilizing reflection of a metal film may be used, but the use of prism utilizing total reflection or the like can increase the transmittance of the transmitted light 716.

Here, the housing 702 preferably includes a mechanism for adjusting the distance and angle between the lens 711 and the display panel 701. This enables focus adjustment, zooming in/out of image, or the like. One or both of the lens 711 and the display panel 701 are preferably configured to be movable in the optical-axis direction, for example.

The housing 702 preferably includes a mechanism capable of adjusting the angle of the reflective plate 712. The position of the display region 706 where images are displayed can be changed by changing the angle of the reflective plate 712. Thus, the display region 706 can be placed at the most appropriate position in accordance with the position of the user's eye.

The display device or the display module of one embodiment of the present invention can be used for the display panel 701. Thus, the electronic device 700 can perform display with extremely high resolution.

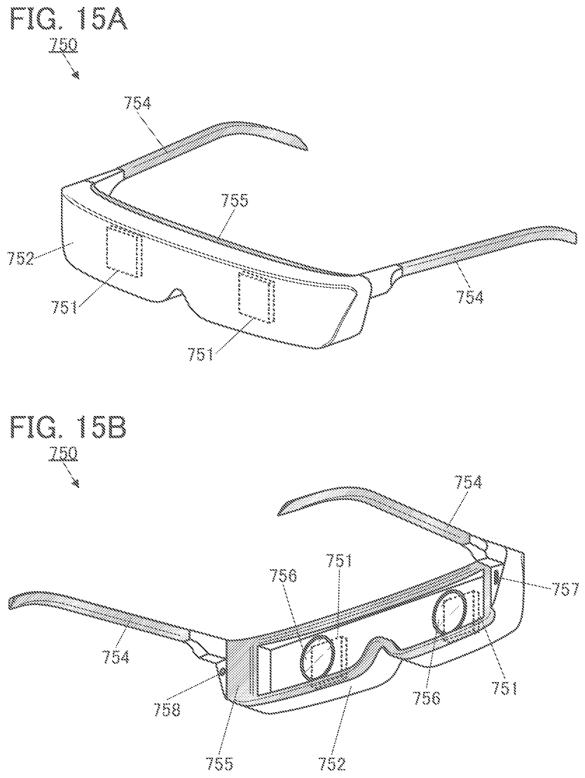

FIG. 15A and FIG. 15B illustrate perspective views of an electronic device 750 that is of a goggle-type. FIG. 15A is a perspective view illustrating the front surface, the top surface, and the left side surface of the electronic device 750, and FIG. 15B is a perspective view illustrating the back surface, the bottom surface, and the right side surface of the electronic device 750.

The electronic device 750 includes a pair of display panels 751, a housing 752, a pair of temples 754, a cushion 755, a pair of lenses 756, and the like. The pair of display panels 751 is positioned to be seen through the lenses 756 inside the housing 752.

The electronic device 750 is an electronic device for VR. A user wearing the electronic device 750 can see an image displayed on the display panel 751 through the lens 756.

Furthermore, when the pair of display panels 751 displays different images, three-dimensional display using parallax can be performed.

An input terminal 757 and an output terminal 758 are provided on the back side of the housing 752. To the input terminal 757, a cable for supplying a video signal from a video output device or the like, power for charging a battery provided in the housing 752, or the like can be connected. The output terminal 758 can function as, for example, an audio output terminal to which earphones, headphones, or the like can be connected. Note that in the case where audio data can be output by wireless communication or sound is output from an external video output device, the audio output terminal is not necessarily provided.

In addition, the housing 752 preferably includes a mechanism by which the left and right positions of the lens 756 and the display panel 751 can be adjusted to the optimal positions in accordance with the position of the user's eye. In addition, a mechanism for adjusting focus by changing the distance between the lens 756 and the display panel 751 is preferably included.

The display device or the display module of one embodiment of the present invention can be used for the display panel 751. Thus, the electronic device 750 can perform display with extremely high resolution. This enables a user to feel high sense of immersion.

The cushion 755 is a portion in contact with the user's face (forehead, cheek, or the like). The cushion 755 is in close contact with the user's face, so that light leakage can be prevented, which increases the sense of immersion. A soft material is preferably used for the cushion 755 so that the cushion 755 is in close contact with the face of the user wearing the electronic device 750. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 755, whereby light leakage can be suitably prevented. Furthermore, using such a material is preferable because it has a soft texture and the user does not feel cold when wearing the device in a cold season, for example. The member in contact with user's skin, such as the cushion 755 or the temple 754, is preferably detachable because cleaning or replacement can be easily performed.

At least part of this embodiment can be implemented in combination with the other embodiments described in this specification as appropriate.

### REFERENCE NUMERALS

100A: display device, 101: substrate, 111: conductive layer, 111a: conductive layer, 111b: conductive layer, 113: conductive layer, 113a: conductive layer, 113b: conductive layer, 114: conductive layer, 114B: conductive layer, 114G: conductive layer, 114R: conductive layer, 115: EL layer, 115a: EL layer, 115b: EL layer, 115B: EL layer, 115G: EL layer, 115R: EL layer, 116: conductive layer, 117: insulator, 120: light-emitting element, 120B: light-emitting element, 120G: light-emitting element, 120R: light-emitting element, 121: insulating layer, 121a: insulating layer, 121b: insulating layer, 131: plug, 161: insulating layer, 162: insulating layer, 163: insulating layer, 164: adhesive layer, 165: coloring layer, 165B: coloring layer, 165G: coloring layer, 165R: coloring layer, 200: display device, 200A: display device, 200B: display device, 200C: display device, 200D: display device, 201: substrate, 202: substrate, 210: transistor, 211: conductive layer, 212: low-resistance region, 213: insulating layer, 214: insulating layer, 215: element isolation layer, 220: transistor, 221: semiconductor layer, 223: insulating layer, 224: conductive layer, 225: conductive layer, 226: insulating layer, 227: conductive layer, 228: insulating layer, 229: insulating layer, 230: transistor, 231: insulating layer, 232: insulating layer, 240: capacitor, 241: conductive layer, 242: conductive layer, 243: insulating layer, 251: conductive layer, 252: conductive layer, 253: conductive layer, 261: insulating layer, 261a: insulating layer, 261b: insulating layer, 262: insulating layer, 263: insulating layer, 264: insulating layer, 265: insulating layer, 271: plug, 271a: conductive layer, 271b: conductive layer, 272: plug, 273: plug, 274: plug, 280: display module, 281: display portion, 282: circuit portion, 283: pixel circuit portion, 283a: pixel circuit, 284: pixel portion, 284a: pixel, 285: terminal portion, 286: wiring portion, 290: FPC, 290b: source driver IC, 400: pixel circuit, 400EL: pixel circuit, 401: circuit, 401EL: circuit, 501: pixel circuit, 502: pixel portion, 504: driver circuit portion, 504a: gate driver, 504b: source driver, 506: protection circuit, 507: terminal portion, 552: transistor, 554: transistor, 562: capacitor, 572: light-emitting element, 700: electronic device, 701: display panel, 702: housing, 703: optical member, 704: mounting portion, 705: camera, 706: display region, 711: lens, 712: reflective plate, 713: reflective surface, 715: light, 716: transmitted light, 750: electronic device, 751: display panel, 752: housing, 754: mounting portion, 755: cushion, 756: lens, 757: input terminal, 758: output terminal, 4411: light-emitting layer, 4412: light-emitting layer, 4413: light-emitting layer, 4420: layer, 4430: layer

1. A method for manufacturing a display device,
wherein a first conductor is formed,
wherein a first insulator is formed over the first conductor,
wherein an opening reaching the first conductor is provided in the first insulator,
wherein a second conductor is formed inside the opening and over the first insulator,
wherein a third conductor is formed by removing part of the second conductor to expose a top surface of the first insulator,
wherein a first light-emitting layer is formed over the third conductor and over the first insulator,
wherein a fourth conductor is formed over the first light-emitting layer, and
wherein a fifth conductor is formed by removing part of the fourth conductor.

2. The method for manufacturing a display device, according to claim 1,
wherein the second conductor comprises a first region in contact with the inside of the opening and a second region in contact with the first insulator.

3. The method for manufacturing a display device, according to claim 1,
wherein formation of the fifth conductor is performed by formation of a resist mask over the fourth conductor and etching using the resist mask.

4. The method for manufacturing a display device, according to claim 1,
wherein the third conductor is formed by removing part of the second conductor by chemical mechanical polishing to expose the top surface of the first insulator.

5. The method for manufacturing a display device, according to claim 4,
wherein a top surface of the third conductor and the top surface of the first insulator are substantially aligned with each other.

6. The method for manufacturing a display device, according to claim 1,
wherein the third conductor is configured to reflect visible light, and
wherein the fifth conductor is configured to transmit visible light.

7. A method for manufacturing a display device,
wherein a first conductor, a second conductor, and a third conductor are formed,
wherein a first insulator is formed over the first conductor, over the second conductor, and over the third conductor,
wherein a first opening reaching the first conductor, a second opening reaching the second conductor, and a third opening reaching the third conductor are provided in the first insulator,
wherein a fourth conductor is formed inside the first opening, inside the second opening, inside the third opening, and over the first insulator,
wherein part of the fourth conductor is removed to expose a top surface of the first insulator, and a fifth conductor over the first conductor, a sixth conductor over the second conductor, and a seventh conductor over the third conductor are formed,
wherein a first light-emitting layer is formed over the fifth conductor, over the sixth conductor, over the seventh conductor, and over the first insulator,
wherein part of the first light-emitting layer is removed to form a second light-emitting layer over the fifth conductor,
wherein a third light-emitting layer is formed over the fifth conductor, over the sixth conductor, over the seventh conductor, over the first insulator, and over the second light-emitting layer,
wherein part of the third light-emitting layer is removed to form a fourth light-emitting layer over the sixth conductor,
wherein a fifth light-emitting layer is formed over the fifth conductor, over the sixth conductor, over the seventh conductor, over the first insulator, over the second light-emitting layer, and over the fourth light-emitting layer, and
wherein part of the fifth light-emitting layer is removed to form a sixth light-emitting layer over the seventh conductor.

8. The method for manufacturing a display device, according to claim 7,
wherein the second light-emitting layer comprises a light-emitting substance emitting blue light,
wherein the fourth light-emitting layer comprises a light-emitting substance emitting green light, and
wherein the sixth light-emitting layer comprises a light-emitting substance emitting red light.

9. The method for manufacturing a display device, according to claim 7,
wherein formation of the second light-emitting layer is performed by formation of a first resist mask over the first light-emitting layer and etching using the first resist mask,
wherein formation of the fourth light-emitting layer is performed by formation of a second resist mask over the third light-emitting layer and etching using the second resist mask, and
wherein formation of the sixth light-emitting layer is performed by formation of a third resist mask over the fifth light-emitting layer and etching using the third resist mask.

10. The method for manufacturing a display device, according to claim 7,
wherein the fifth conductor, the sixth conductor, and the seventh conductor are formed by removing part of the fourth conductor by chemical mechanical polishing to expose the top surface of the first insulator.

11. The method for manufacturing a display device, according to claim 10,
wherein a top surface of the fifth conductor, a top surface of the sixth conductor, a top surface of the seventh conductor, and the top surface of the first insulator are substantially level with each other.

12. A display device comprising:
a first conductor;
a first insulator over the first conductor;
a second conductor provided inside an opening of the first insulator;
a first light-emitting layer in contact with a top surface of the second conductor and a top surface of the first insulator; and
a third conductor in contact with a top surface of the first light-emitting layer.

13. The display device according to claim 12,
wherein the first conductor and the second conductor are electrically connected to each other.

14. The display device according to claim 12,
wherein the second conductor comprises a region in contact with a sidewall of the opening.

15. The display device according to claim 12,
wherein the top surface of the second conductor and the top surface of the first insulator are substantially level with each other.
